(19) United States
(12) Patent Application Publication
(10) Pub. No.: US 2024/0071802 A1
(43) Pub. Date: Feb. 29, 2024

(54) OPERATIONS OF ROBOT APPARATUSES WITHIN RECTANGULAR MAINFRAMES

(71) Applicant: Applied Materials, Inc., Santa Clara, CA (US)

(72) Inventors: Paul Z. Wirth, Kalispell, MT (US); Damon K. Cox, Jarrell, TX (US); Rajkumar Thanu, Lathrop, CA (US); Karuppasamy Muthukamatchi, Madurai (IN); Jeffrey C. Hudgens, San Francisco, CA (US)

(21) Appl. No.: 18/234,453

(22) Filed: Aug. 16, 2023

(30) Foreign Application Priority Data
Aug. 26, 2022 (IN) 202241048706
Feb. 20, 2023 (IN) 202341011390

(51) Int. Cl. H01L 21/687; B25J 9/04; B25J 11/00; H01L 21/67

(52) U.S. Cl. CPC H01L 21/68707; B25J 9/043; B25J 11/0095; H01L 21/67167; H01L 21/67201

(57) ABSTRACT

A robot apparatus with variable end effector pitch is provided suitable for accommodating varying pitches, e.g., between two adjacent processing chambers or between two adjacent load lock chambers. The robot apparatus may operate in dual substrate handling mode, single substrate handling mode, or a combination thereof. The robot apparatus may also be an off-axis robot. A variety of robot apparatuses according to various embodiments, electronic device processing systems including such robot apparatuses, and methods of use thereof are described.

### CROSS-REFERENCE TO RELATED APPLICATIONS

This application claims the benefit of Indian Provisional Patent Application No. 202241048706, filed on Aug. 26, 2022 and entitled “OPERATIONS OF ROBOT APPARATUSES WITHIN RECTANGULAR MAINFRAMES”, and Indian Provisional Patent Application No. 202341011390, filed on Feb. 20, 2023 and entitled “OPERATIONS OF ROBOT APPARATUSES WITHIN RECTANGULAR MAINFRAMES”, the entire contents of which are incorporated by reference herein.

### TECHNICAL FIELD

Embodiments of the present application relate to robots including multiple end effectors and electronic device processing devices and methods including robots with multiple end effectors.

### BACKGROUND

Processing of substrates in semiconductor electronic device manufacturing may include a combination of different processes applied in the same substrate processing system. For example, the processes may include chemical vapor deposition/atomic layer deposition (CVD/ALD) and physical vapor deposition (PVD) applied within the same tool or platform. These processes may be applied using different configurations of processing chambers coupled to a mainframe. Robots are located in a transfer chamber of the mainframe and are configured to move substrates between the various processing chambers.

### SUMMARY

In some embodiments, a robot apparatus is provided. The robot apparatus includes a lower arm configured to rotate about a first rotational axis, an upper arm rotatably coupled to the lower arm at, and configured to rotate about, the first rotational axis, a first blade including at least a first end effector rotatably coupled to the lower arm at, and configured to rotate about, a second rotational axis that is spaced away from the first rotational axis, and a second blade including at least a second end effector rotatably coupled to the upper arm at, and configured to rotate about, a third rotational axis that is spaced away from the first rotational axis. The robot apparatus is configured to extend the first end effector into a first processing chamber and extend the second end effector into a second processing chamber, wherein the first processing chamber and the second processing chamber are separated by a first pitch, retract the first end effector and the second end effector into a rectangular mainframe while maintaining a distance between the first end effector and the second end effector bounded by the first pitch throughout a retraction process, and fold the first end effector and the second end effector inward within a sweep diameter defined by a width of the rectangular mainframe.

In some embodiments, an electronic device processing system is provided. The electronic device processing system includes a rectangular mainframe, a first load lock chamber and a second load lock chamber attached to a first side of the rectangular mainframe, wherein a first port of the first load lock chamber and a second port of the second load lock chamber are spaced apart horizontally by a first pitch, a first processing chamber and a second processing chamber attached to a second side of the rectangular mainframe, wherein a third port of the first processing chamber and a fourth port of the second processing chamber are spaced apart horizontally by a second pitch that is greater than the first pitch, and a robot apparatus housed within the rectangular mainframe. The robot apparatus includes a lower arm configured to rotate about a first rotational axis, an upper arm rotatably coupled to the lower arm at, and configured to rotate about, the first rotational axis, a first blade including at least a first end effector rotatably coupled to the lower arm at, and configured to rotate about, a second rotational axis that is spaced away from the first rotational axis, and a second blade including at least a second end effector rotatably coupled to the upper arm at, and configured to rotate about, a third rotational axis that is spaced away from the first rotational axis. The robot apparatus is configured to extend the first end effector into the first processing chamber and extend the second end effector into the second processing chamber, retract the first end effector and the second end effector into the rectangular mainframe while maintaining a distance between the first end effector and the second end effector bounded by the second pitch throughout retraction, and fold the first end effector and the second end effector inward within a sweep diameter defined by a width of the rectangular mainframe.

In some embodiments, a method is provided. The method includes, for a robot apparatus including a lower arm configured to rotate about a first rotational axis, an upper arm rotatably coupled to the lower arm at, and configured to rotate about, the first rotational axis, a first blade including at least a first end effector rotatably coupled to the lower arm at, and configured to rotate about, a second rotational axis that is spaced away from the first rotational axis, and a second blade including at least a second end effector rotatably coupled to the upper arm at, and configured to rotate about, a third rotational axis that is spaced away from the first rotational axis: extending, by the robot apparatus, the first end effector into a first processing chamber to retrieve a first substrate, extending, by the robot apparatus, the second end effector into a second processing chamber to retrieve a second substrate, wherein the first processing chamber and the second processing chamber are separated by a first pitch, retracting, by the robot apparatus, the first end effector and the second end effector into a rectangular mainframe while maintaining a distance between the substrates bounded by the first pitch throughout retraction, and folding, by the robot apparatus, the first end effector and the second end effector inward within a sweep diameter defined by a width of the rectangular mainframe.

Numerous other aspects and features are provided in accordance with these and other embodiments of the disclosure. Other features and aspects of embodiments of the disclosure will become more fully apparent from the following detailed description, the claims, and the accompanying drawings.

### BRIEF DESCRIPTION OF DRAWINGS

The drawings, described below, are for illustrative purposes only and are not necessarily drawn to scale. The drawings are not intended to limit the scope of the disclosure in any way. Wherever possible, the same or like reference numbers will be used throughout the drawings to refer to the same or like parts.

FIG. 1 illustrates a schematic top view of a substrate processing system including a robot apparatus housed within a mainframe according to the disclosed embodiments.

FIG. 2 illustrates a top-down view of a substrate processing system including a robot apparatus housed within a rectangular mainframe according to some embodiments.

FIG. 3A illustrates a perspective view of a robot apparatus according to some embodiments.

FIG. 3B illustrates a top-down view of the robot apparatus of FIG. 3A in a folded configuration (e.g., a chamber preposition or a load lock preposition).

FIG. 3C illustrates a top-down view of the robot apparatus of FIG. 3A in an extended configuration (e.g., a twin chamber reach or a dual load lock reach in a dual substrate handling mode).

FIGS. 4A-4C illustrate top-down views of the operation of a robot apparatus housed within a rectangular mainframe according to some embodiments.

FIGS. 5A-5D illustrate top-down views of the operation of a robot apparatus housed within a rectangular mainframe according to some embodiments.

FIGS. 6-7 illustrate example robot apparatuses having motion driving assemblies according to some embodiments.

FIG. 8A illustrates a perspective view of a robot apparatus according to some embodiments.

FIG. 8B illustrates a top-down view of the robot apparatus of FIG. 8A according to some embodiments.

FIGS. 9A-9C illustrate perspective views of the robot apparatus of FIGS. 8A-8B housed within a substrate processing system according to some embodiments.

FIGS. 10A-10H illustrate top-down views of the operation of a robot apparatus housed within a rectangular mainframe according to some embodiments.

FIGS. 11A-11B illustrate example robot apparatuses having motion driving assemblies according to some embodiments.

FIG. 12 illustrates an example robot apparatus having a motion driving assembly according to some embodiments.

FIG. 13 illustrates an example robot apparatus having a motion driving assembly according to some embodiments.

FIG. 14 illustrates a top-down view of the operation of a robot apparatus housed within a rectangular mainframe according to some embodiments.

FIGS. 15A-15B illustrate example robot apparatuses having motion driving assemblies according to some embodiments.

FIGS. 16-17 illustrate top-down views of operations of robot apparatuses housed within rectangular mainframes according to some embodiments.

FIGS. 18A-18B illustrate side views of a robot blade with a pair of end effectors and a process chamber according to some embodiments.

FIG. 19 illustrates an example robot apparatus having a motion driving assembly according to some embodiments.

FIGS. 20A-20C illustrate side views of a robot blade with a pair of end effectors according to some embodiments.

FIGS. 21A-21B illustrate side views of a robot blade with a pair of end effectors and a process chamber according to some embodiments.

### DETAILED DESCRIPTION

Reference will now be made in detail to the example embodiments provided, which are illustrated in the accompanying drawings. Features of the various embodiments described herein may be combined with each other unless specifically noted otherwise.

Electronic device processing systems may implement a combination of multiple substrate manufacturing processes. These substrate manufacturing processes may include chemical vapor deposition/atomic layer deposition (CVD/ALD) processes, annealing processes, etch processes, physical vapor deposition (PVD) and/or other processes. The electronic device processing systems may include a variety of different processing chambers and load lock chambers to implement the combination of multiple substrate manufacturing processes. These processing chambers and load lock chambers may each include one or more processing locations on which substrates are positioned for processing. Processing locations in different processing chambers and/or load lock chambers may be separated by different distances (e.g., pitches) depending on a physical arrangement or processing chambers, the type of manufacturing process to be implemented within each processing chamber and/or the configuration of the processing chambers. Pitch may refer to a spacing between ports of adjacent chambers (e.g., between two load lock chambers spaced apart horizontally or between two processing chambers spaced apart horizontally) in embodiments.

A robot apparatus can be housed within a mainframe that includes a transfer chamber. In some embodiments, multiple load lock chambers and/or multiple processing chambers are connected to sides or facets of the transfer chamber. The robot apparatus can be a dual end effector robot apparatus having a pair of end effectors for transferring substrates between load lock chambers and/or transfer chambers. The robot apparatus may by designed such that a pitch or separation between the dual end effectors is adjustable, and may be further designed such that the end effectors may be positioned both for single substrate handling (in which a single substrate is removed from and/or inserted into a processing chamber or load lock) and may further be positioned for dual substrate handling (in which two substrates are removed from and/or inserted into a processing chamber or load lock).

A robot apparatus can be adapted and configured to place substrates within and/or remove substrates from, a pair of processing chambers (e.g., side-by-side processing chambers) and/or load lock chambers simultaneously. However, existing robot apparatuses may not be able to maintain a constant pitch with respect to both an extended position of the dual end effectors and a retracted position of the dual end effectors. Additionally, the pitch at the retracted position of the dual end effectors may cause the operation of the robot apparatus to exceed sweep diameter specifications with respect to geometric constraints of a mainframe that houses the robot apparatus within the transfer chamber. A sweep diameter refers to the diameter of the circle during the rotational motion of the links of the robot apparatus in a retracted posture. This is particularly true with respect to a robot apparatus housed within a rectangular mainframe in which a length of the mainframe is greater than a width of the rectangular mainframe, as the sweep diameter may be constrained by the width of the rectangular mainframe. The processing chambers can be positioned along one or more sides (e.g., the lengths) of the rectangular mainframe, while the load lock chambers can be positioned along one or more sides (e.g., the widths) of the rectangular mainframe. In some embodiments, a pitch between pairs of processing chambers may be different than a pitch between pairs of load lock chambers.

To address at least the above noted drawbacks, the robot apparatuses described herein can operate within a rectangular mainframe in a single substrate processing mode, a dual substrate processing mode, or a combination thereof. This added flexibility and independent access capability permits sequential loading and unloading of various processing chambers and/or load lock chambers. This capability also allows the robot apparatus to continue operating even when one processing chamber or load lock chamber out of a pair of adjacent processing chambers or load lock chambers is inoperative.

With respect to processing chambers, while operating in a dual substrate processing mode, a robot apparatus housed within a rectangular mainframe can simultaneously extend a pair of end effectors into respective processing chambers to obtain (or drop off) respective substrates or wafers, simultaneously retract the pair of end effectors inside the rectangular mainframe, and fold the arms at the end of the retraction to allow rotation within a particular width of the rectangular mainframe. With respect to load lock chambers, while operating in a dual substrate processing mode, a robot apparatus housed within a rectangular mainframe can independently extend a pair of end effectors into respective load lock chambers to obtain respective substrates or wafers, and independently retract the pair of end effectors into the rectangular mainframe. As another example, while operating in a dual substrate processing mode, a robot apparatus housed within a rectangular mainframe can perform coordinated extension of a pair of end effectors into respective load lock chambers to obtain respective substrates or wafers, and coordination retraction of the pair of end effectors into the rectangular mainframe, in which a first end effector of the pair lags behind a second effector of the pair. As yet another example, while operating in a dual substrate processing mode, a robot apparatus housed within a rectangular mainframe can simultaneously extend a pair of end effectors into respective load lock chambers to obtain respective substrates or wafers, and simultaneously retract the pair of end effectors inside the rectangular mainframe. Further details regarding the robot apparatus will now be described in further detail.

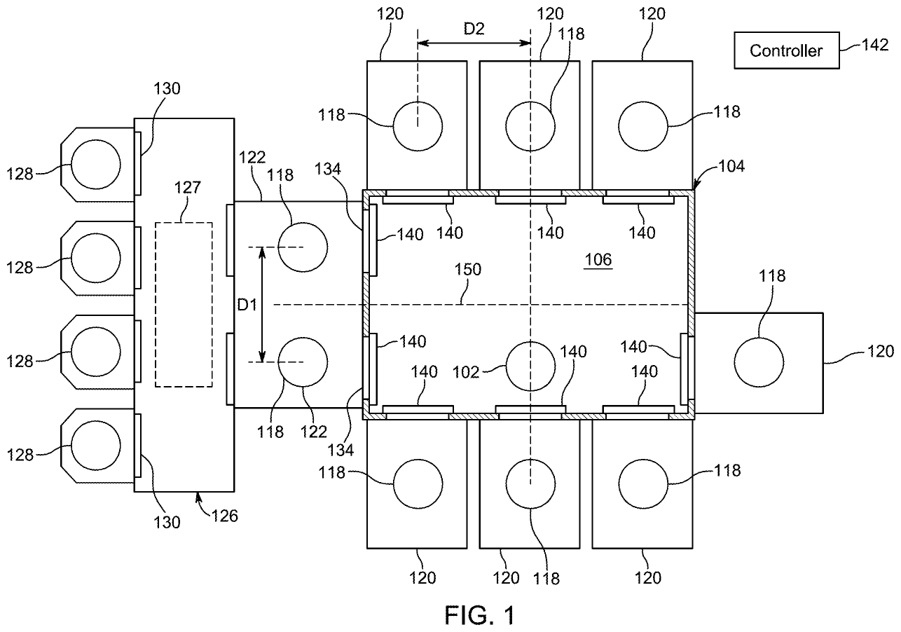

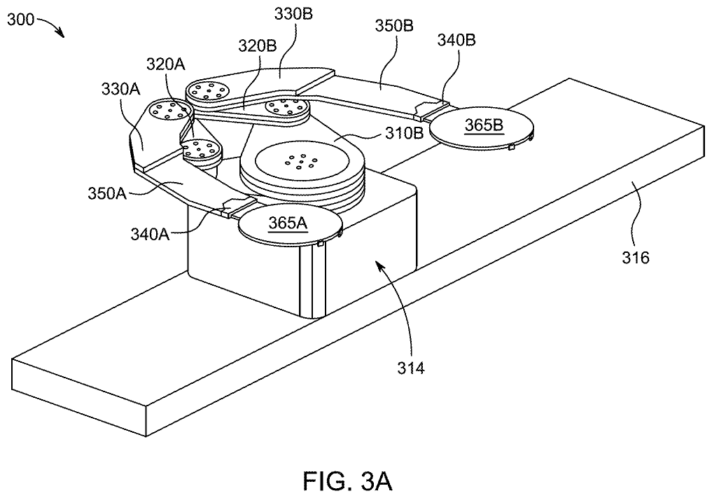

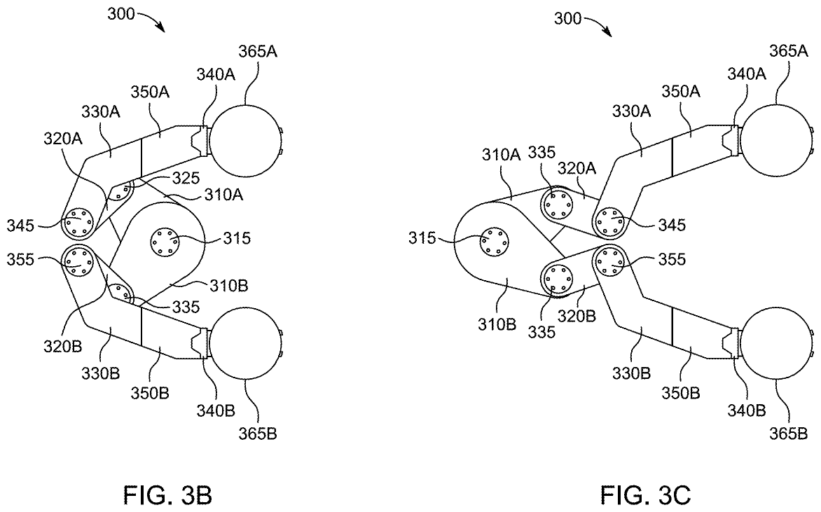

FIG. 1 illustrates a schematic top view of a substrate processing system 100 including a robot apparatus 102 according to disclosed embodiments. The substrate processing system 100 may include a mainframe 104 including a transfer chamber 106 formed by walls thereof. Though the mainframe 104 is illustrated to be a rectangular mainframe, the mainframe 104 may alternatively have other shapes. For example, the mainframe may have more or fewer sides than four, such as five sides, six sides, seven sides, and so on. In such embodiments, different sides may have the same or different sizes (e.g., lengths or widths). The transfer chamber 106 may be configured to operate in a vacuum, for example. The transfer chamber may have a center 150. The robot apparatus 102 may be at least partially located in the transfer chamber 106 and may be configured to be operable therein. The robot apparatus 102 may include a body (e.g., 314 in FIG. 3A) that is configured to be attached to a wall (e.g., the floor) of the transfer chamber 106. The robot apparatus 102 may be “off axis” or “off center,” which as used herein, refers to the robot apparatus having at least one lower arm configured to rotate about a first rotational axis that is offset from the center 150 of the transfer chamber 106.

The robot apparatus 102 may be configured to pick and/or place substrates 118 (sometimes referred to as a “wafers” or “semiconductor wafers”) to and from different destinations. The destinations may be processing chambers coupled to the transfer chamber 106. The destinations may also be load lock chambers coupled to transfer chamber 106. For example, the destinations may be one or more processing chambers 120 and one or more load lock chambers 122 that may be coupled to transfer chamber 106. The mainframe 104 may include more or fewer processing chambers 120 than illustrated in FIG. 1 and more or fewer load lock apparatus 122 than illustrated in FIG. 1.

The processing chambers 120 may be configured to carry out any number of process steps on the substrates 118, such as deposition, oxidation, nitration, etching, polishing, cleaning, lithography, or the like. In FIG. 1, seven processing chambers 120 are shown coupled to various sides of transfer chamber 106. However, it should be noted that other configurations that include more or fewer processing chambers are also feasible and contemplated by the instant disclosure. In certain embodiments, the number of processing chambers coupled to the transfer chamber 106 ranges from 4 to 24. In certain embodiments, the number of processing chambers coupled to the transfer chamber 106 ranges from 4 to 20. In certain embodiments, the number of processing chambers coupled to the transfer chamber 106 ranges from 5 to 16. In certain embodiments, the number of processing chambers coupled to the transfer chamber 106 ranges from 6 to 10. In some embodiments, the transfer chamber 106 is a linear transfer chamber having two longer sides and two shorter sides. For example, the transfer chamber 106 can be included within a rectangular mainframe 104. In other embodiments, the transfer chamber may have more than four sides, such as five sides, six sides, seven sides, eight sides, and so on. The multiple sides may have a same size (e.g., a same length) and/or different sizes.

The load lock chambers 122 may be configured to interface with a factory interface 126. The factory interface 126 may include a load/unload robot 127 (shown as a dotted box) configured to transport substrates 118 to and from substrate carriers 128 (e.g., Front Opening Unified Pods (FOUPs)) docked at load ports 130 of the factory interface 126. Another load/unload robot may transfer the substrates 118 between the substrate carriers 128 and the load lock chambers 122 in any sequence or order.

In some embodiments, two adjacent load lock chambers 122 are horizontally spaced by a first pitch D1. In some embodiments, the first pitch D1 between centers of the two adjacent load lock chambers 122 may be in a range of about 20 inches to about 25 inches. In some embodiments, the first pitch D1 between centers of two adjacent load lock chambers 122 may be in a range of about 21 inches to about 23 inches. In some embodiments, the first pitch D1 between centers of two adjacent load lock chambers 122 may be about 22 inches. Other distances for the first pitch D1 may also be possible.

In some embodiments, at least one pair of two adjacent processing chambers 120 are horizontally spaced by a second pitch D2 that is different from the first pitch D1 (e.g., second pitch D2 may be greater than first pitch D1). In some embodiments, the second pitch D2 between centers of the two adjacent processing chambers 120 may be in a range of about 32 inches to about 40 inches. In some embodiments, the second pitch D2 between centers of two adjacent processing chambers 120 may be in a range of about 34 inches to about 38 inches. In some embodiments, the second pitch D2 between centers of two adjacent processing chambers 120 may be about 36 inches. Other distances for the second pitch D2 may also be possible.

One or more of the load lock chambers 122 may be accessed by the robot apparatus 102 through slit valves 134. One or more of the processing chambers 120 may be accessed by the robot apparatus 102 through slit valves 140.

In some embodiments, the robot apparatus 102 can include a lower shoulder and an upper shoulder each configured to rotate about a first rotational axis, a first arm rotatably coupled to the lower shoulder at a second rotational axis, a second arm rotatably coupled to the upper shoulder at a third rotational axis, and a first forearm rotatably coupled to the first arm at a fourth rotational axis and a second forearm rotatably coupled to the second arm at a fifth rotational axis. The first forearm and the second forearm each have a different length from the lower arm and the upper arm. The robot apparatus 102 can further include a first end effector coupled to the first forearm and a second end effector coupled to the second forearm. In some embodiments, the first end effector and the second end effector of robot apparatus 102 are co-planar. Further details regarding the robot apparatus 102 are described below with reference to FIGS. 3A-7.

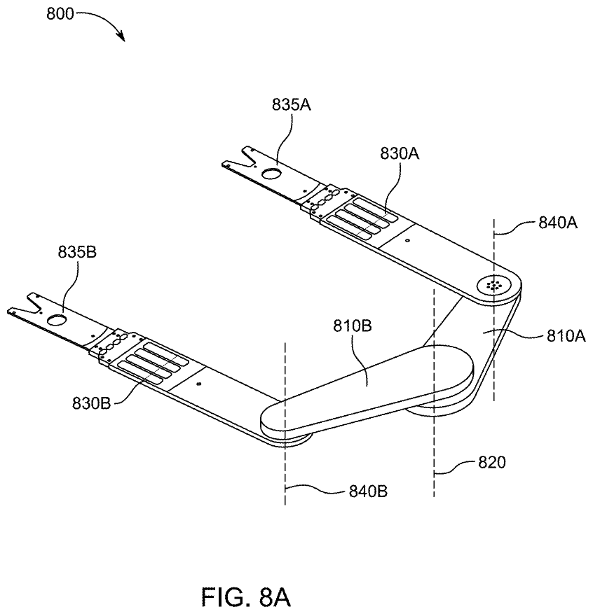

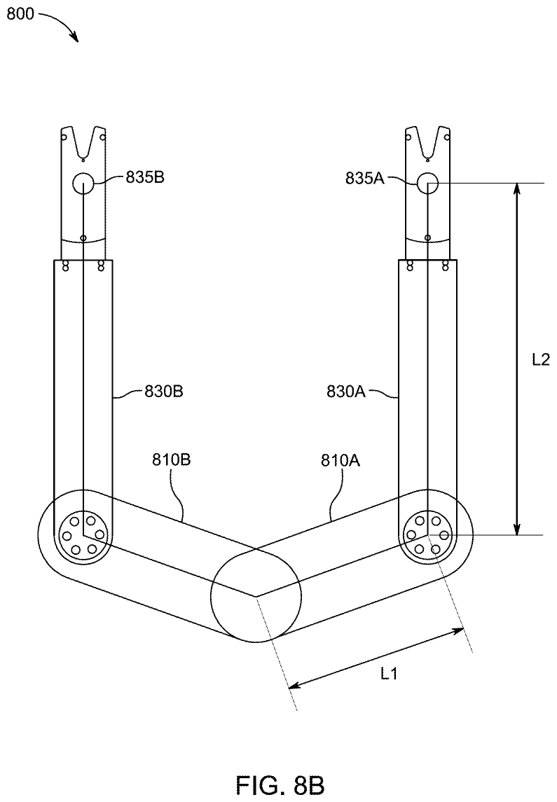

In some embodiments, the robot apparatus 102 can include a lower arm configured to rotate about a first rotational axis, an upper arm rotatably coupled to the lower arm at, and configured to rotate about, the first rotational axis, a first end effector rotatably coupled to the lower arm at, and configured to rotate about, a second rotational axis that is spaced away from the first rotational axis, and a second end effector rotatably coupled to the upper arm at, and configured to rotate about, a third rotational axis that is spaced away from the first rotational axis. In certain embodiments, the first end effector and the second end effector of robot apparatus 102 are co-planar. Further details regarding the robot apparatus 102 are described below with reference to FIGS. 8-13.

The slit valves 134 and 140 may have a slit valve width that allows the robot apparatus 102, and particularly, the first end effector and the second end effector, to access them in both, dual substrate handling mode and in single substrate handling mode. In certain embodiments, the first end effector and/or the second end effector access the slit valve(s) 134 and/or slit valve(s) 140 orthogonally (relative to the horizontal opening of slit valve 134 or of slit valve 140). In alternative embodiments, the first end effector and/or the second end effector access the slit valve(s) 134 and/or the slit valve(s) 140 at an angle (relative to the horizontal center line of slit valve 134 or of slit valve 140). The first and/or the second end effector(s) may access one or more of slit valve(s) 134 and/or 140 at an angle ranging from about 0° to about 20°, from about 5° C. to about 17°, or from about 7° to about 14° relative, when measured relative to the horizontal center line of slit valve 134 or of slit valve 140.

“Dual substrate handling mode,” as used herein, refers to the robot apparatus 102 concurrently accessing two adjacent chambers (e.g., processing chambers 120 or load lock chambers 122) using the first and second end effectors. In some embodiments, dual substrate handling mode includes simultaneously extending the first and second end effectors into respective first and second chambers. In some embodiments, dual substrate handling mode includes performing coordinated extension of the first and second end effectors into the respective first and second chambers, where the first end effector extends into the first chamber at a first time and the second end effector extends into the second chamber at a second time after the first time and prior to full retraction of the first end effector (e.g., lagged extension). In some embodiments, dual substrate handling mode includes independently extending the first and second end effectors into the respective first and second chambers (e.g., the first end effector extends into, and retracts from, the first chamber, and the second end effector extends into the second chamber after the first end effector has completed retraction).

“Single substrate handling mode,” as used herein, refers to the robot apparatus accessing one load lock chamber (e.g., load lock chamber 122) or one processing chamber (e.g., processing chamber 120). When the robot apparatus 102 is in single substrate handling mode, the first end effector and the second end effector are to independently rotate about one or more additional axis that are different from the first rotational axis and from the second rotational axis to align the first end effector and the second end effector at a configuration suitable for one of the first end effector or the second end effector to access one load lock chamber or one processing chamber. The second end effector that is not being used to pick or place a substrate may be rotated out of the way so that it does not interfere with picking or placing of the substrate by the first end effector that is performing picking and placing of a substrate.

The term “access,” as used herein with reference to the one or more of the end effectors accessing one or more load lock chamber(s) and/or processing chamber(s) refers to the end effector(s) accessing said chamber to pick up substrate(s), drop off substrate(s), exchange substrate(s), and/or any other operation those skilled in the art would understand to be performed by end effectors accessing a load lock chamber(s) and/or a processing chamber(s).

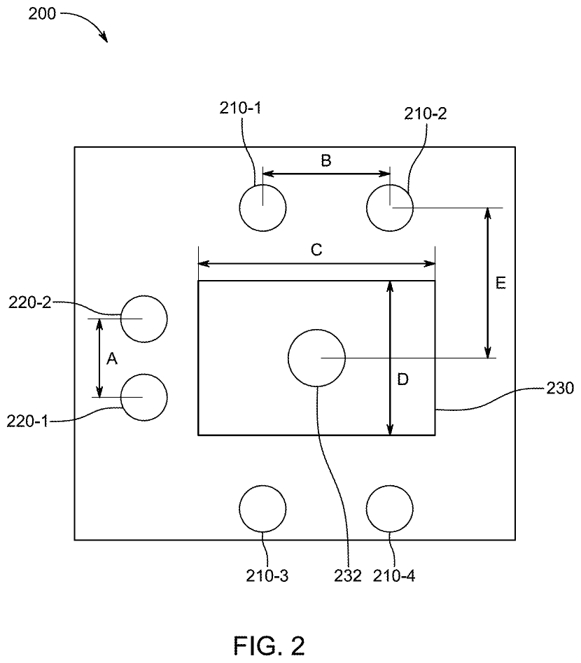

Various embodiments of robot apparatus 102 are contemplated herein, as will be illustrated in further detail with respect to FIGS. 2-13. The mode of operation for dual substrate handling mode and single substrate handling mode may vary for different embodiments of robot apparatus 102, as will be illustrated in further detail with respect to FIGS. 2-13.

A controller 142 may be in communication with the robot apparatus 102. The robot apparatus 102 may be controlled by suitable commands from the controller 142. The controller 142 may also control the slit valves 134 and 140 and other components and processes taking place within the mainframe 104, load lock chambers 122, and processing chambers 120.

FIG. 2 illustrates a top-down view of a substrate processing system (“system”) 200 according to some embodiments. As shown, the system 200 includes a number of processing chambers including adjacent processing chambers 210-1 and 210-2, and adjacent processing chambers 210-3 and 210-4, and a number of load lock chambers including adjacent load lock chambers 220-1 and 220-2. As further shown, the system 200 includes a rectangular mainframe 230 having a robot apparatus 232 housed therein (e.g., similar to the robot apparatus 102 housed within the mainframe 104 of FIG. 1).

As shown, the load lock chambers 220-1 and 220-2 are spaced apart by a first pitch “A” as measured between the centers of the load lock chambers 220-1 and 220-2 and/or between the centers of ports of the load lock chambers. As compared to square mainframes, the first pitch A between the centers of the load lock chambers 220-1 and 220-2 can be smaller as a result of the dimensions of the rectangular mainframe 230. In some embodiments, the first pitch A is in a range of about 20 inches to about 25 inches. In some embodiments, the first pitch A is in a range of about 21 inches to about 23 inches. In some embodiments, the first pitch A is about 22 inches. Other distances for the first pitch A may also be possible.

As further shown, at least the processing chambers 210-1 and 210-2 are spaced apart by a second pitch “B” as measured between the centers of the processing chambers 210-1 and 210-2. The second pitch B can be different from the first pitch A. For example, the second pitch B can be greater than first pitch A). As compared to square mainframes, the second pitch B between the centers of the processing chambers 210-1 and 210-2 can be smaller as a result of the dimensions of the rectangular mainframe 230. In some embodiments, the second pitch B is in a range of about 32 inches to about 40 inches. In some embodiments, the second pitch B is in a range of about 34 inches to about 38 inches. In some embodiments, the second pitch B is about 36 inches. Other distances for the second pitch B may also be possible.

As further shown, the rectangular mainframe 230 can have a length “C”. In some embodiments, the length C is in a range of about 40 inches to about 80 inches. In some embodiments, the length C is in a range of about 50 inches to about 70 inches. In some embodiments, the length C is about 67 inches (e.g., about 1700 millimeters (mm)). Other distances for the length C may also be possible. The rectangular mainframe 230 can have a width “D” different from the length C. In some embodiments, the width D is in a range of about 20 inches to about 60 inches. In some embodiments, the width D is in a range of about 30 inches to about 50 inches. In some embodiments, the width D is about 43 inches (e.g., about 1100 mm). Other distances for the width D may also be possible. The ratio of the length C to the width D (i.e., C:D) may be about 1.545.

As further shown, the robot apparatus 232 and the processing chamber 210-2 can be separated by a distance “E” as measured between the centers of the robot apparatus 232 and the processing chamber 210-2. In some embodiments, the distance E is in a range of about 20 inches to about 60 inches. In some embodiments, the distance E is in a range of about 30 inches to about 50 inches. In some embodiments, the distance E is about 42 inches.

With respect to at least the processing chambers 210-1 and 210-2, the robot apparatus 232 can extend its end effectors (not shown in FIG. 2) into the processing chambers 210-1 and 210-2, either in a dual substrate handling mode (e.g., simultaneously, coordinated extension and retraction, or independently) to retrieve respective substrates, or in a single substrate handling mode to retrieve a single substrate, and then retract the end effector(s) inside of the rectangular mainframe 230 to maintain the second pitch B. However, with respect to conventional robot apparatus designs, the retracted position of the robot apparatus 232 can exceed a sweep diameter defined by the width D of the rectangular mainframe 230 (e.g., about 1100 mm). Thus, conventional robot motion control mechanisms may not support dual substrate handling modes that can maintain a distance between the first end effector and the second end effector bounded by the second pitch B at both the extended and retracted positions (e.g., substantially or approximately equal to the second pitch B) in accordance with the sweep diameter defined by the width D.

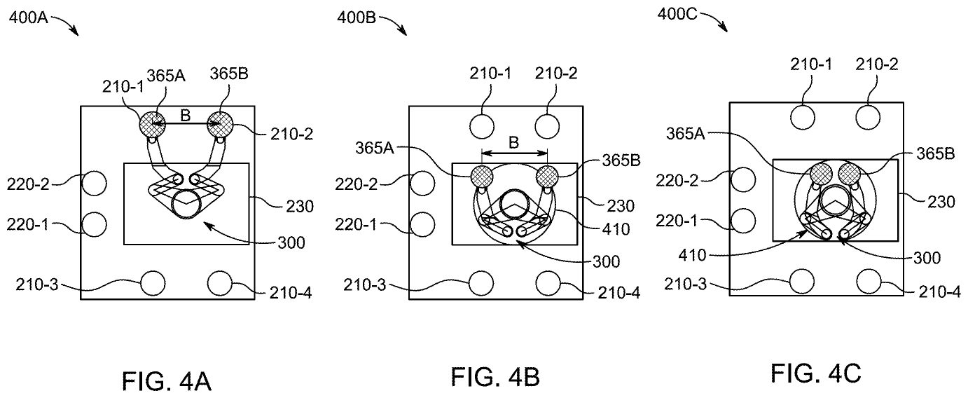

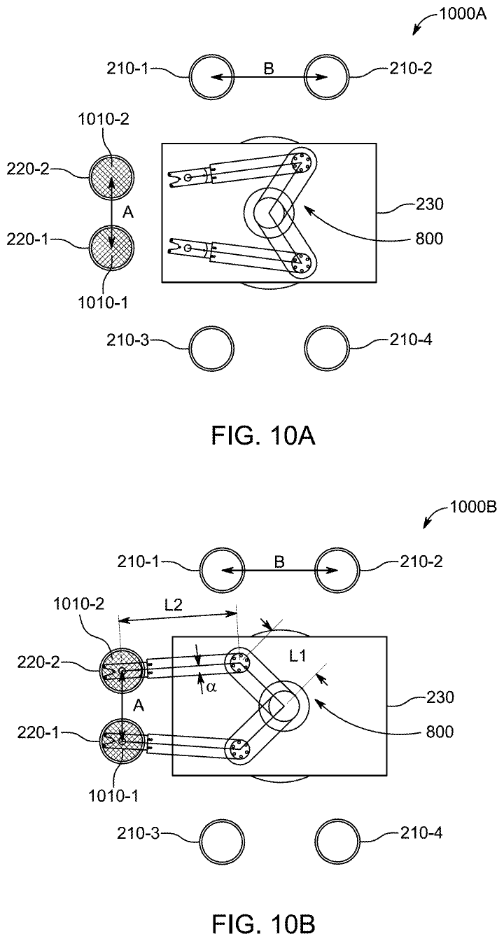

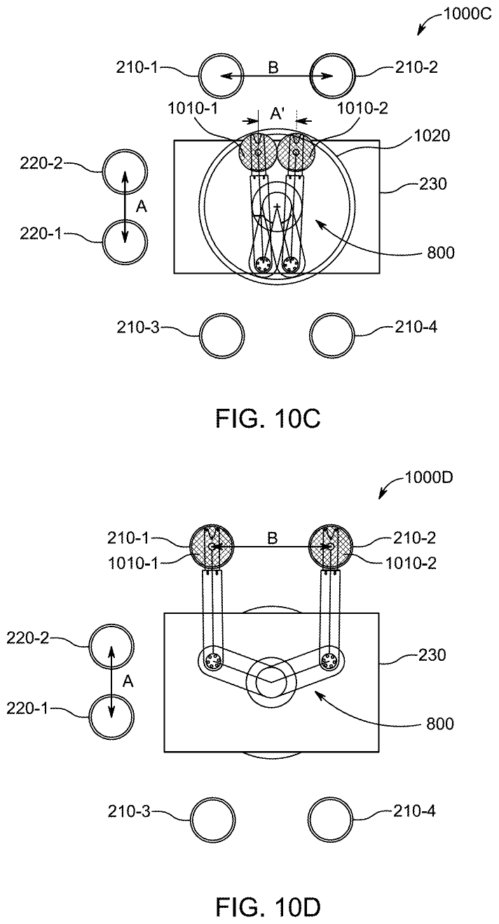

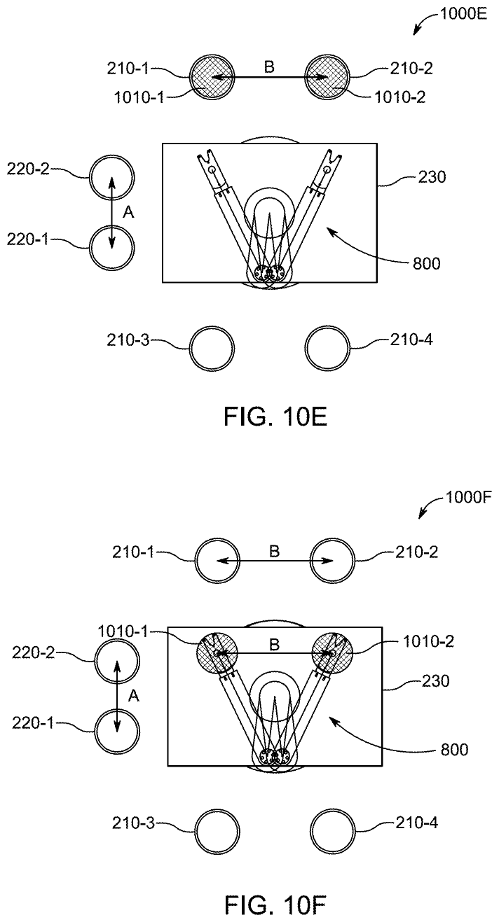

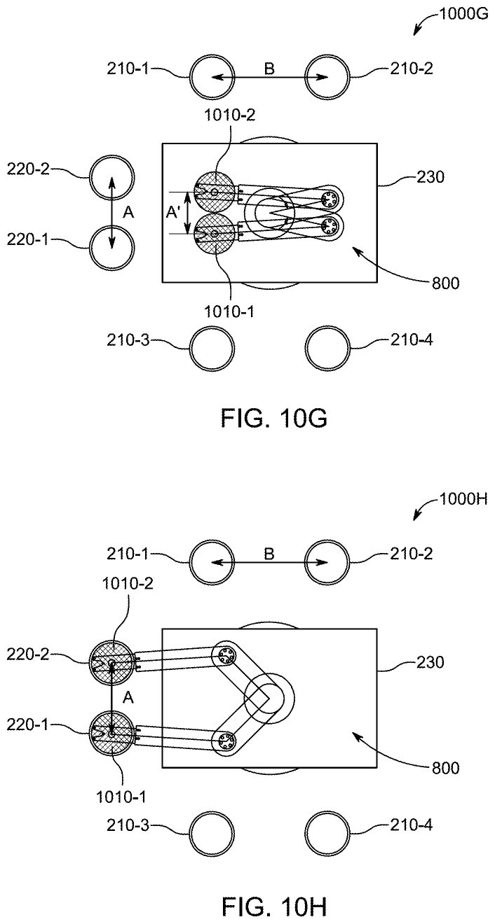

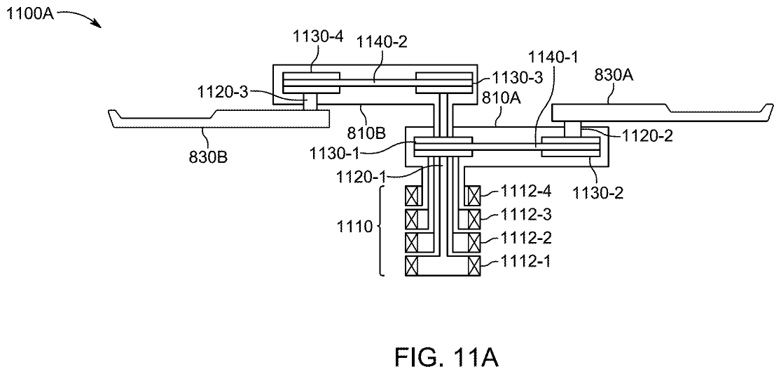

As will be described below with reference to FIGS. 4A-4C and FIGS. 10A-10H, in order to maintain the distance between the first end effector and the second end effector bounded by the second pitch B (e.g., approximately or substantially equal to the second pitch B) at both the extended and retracted positions in accordance with the sweep diameter defined by the width D with respect to a dual substrate handling mode (and thus improve processing throughput), the robot apparatus 232 described herein can be provided with a motion control mechanism that can enable the end effectors to be folded inwards at the end of retraction to enable rotation within the sweep diameter defined by the width D of the rectangular mainframe 230. For example, if the width D is about 1100 mm, then the end effectors of the robot apparatus 232 can be folded inwards after retraction at about 312 mm or about 12 inches to achieve a sweep diameter of about 1100 mm. More specifically, the robot apparatus 232 can be controlled with a combination of motors and cam pulleys designed to enable the compression or folding operation after retraction. Once the robot apparatus 232 is in a fully retracted state with the end effectors folded inwards, the robot apparatus 232 can be rotated without the robot apparatus 232 and/or supported substrates colliding with a wall of the rectangular mainframe.

With respect to at least the load lock chambers 220-1 and 220-2, the robot apparatus 232 can extend its end effectors (not shown in FIG. 2) into the load lock chambers 220-1 and 220-2, either in a dual substrate handling mode or a single substrate handling mode, to retrieve respective substrates, and then retract the end effectors inside of the rectangular mainframe 230. However, with respect to conventional robot apparatus designs, there may not be sufficient clearance to retract the end effectors based on the width D of the rectangular mainframe 230, such that appendages of the robot apparatus 232 can collide with the walls of the rectangular mainframe 230. Thus, conventional robot motion control mechanisms may not be able to avoid collision with the walls of the rectangular mainframe 230.

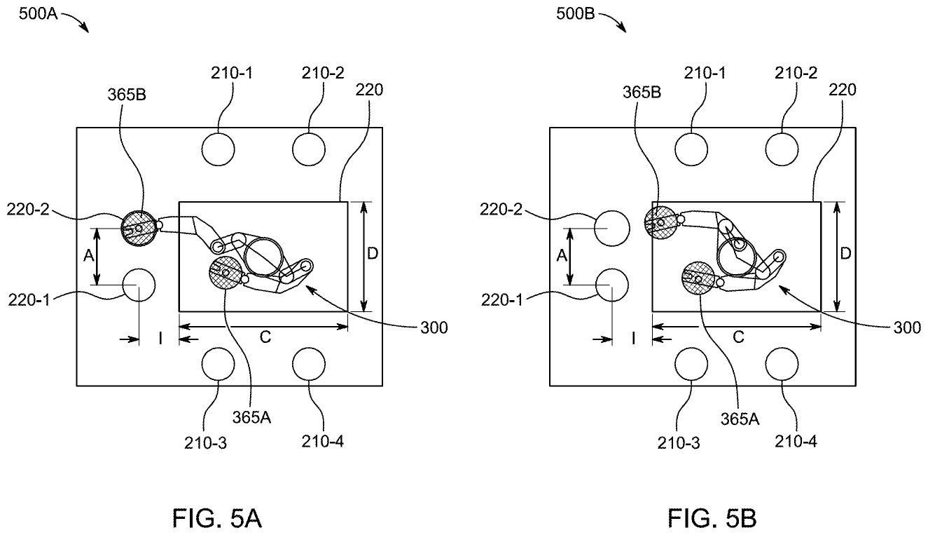

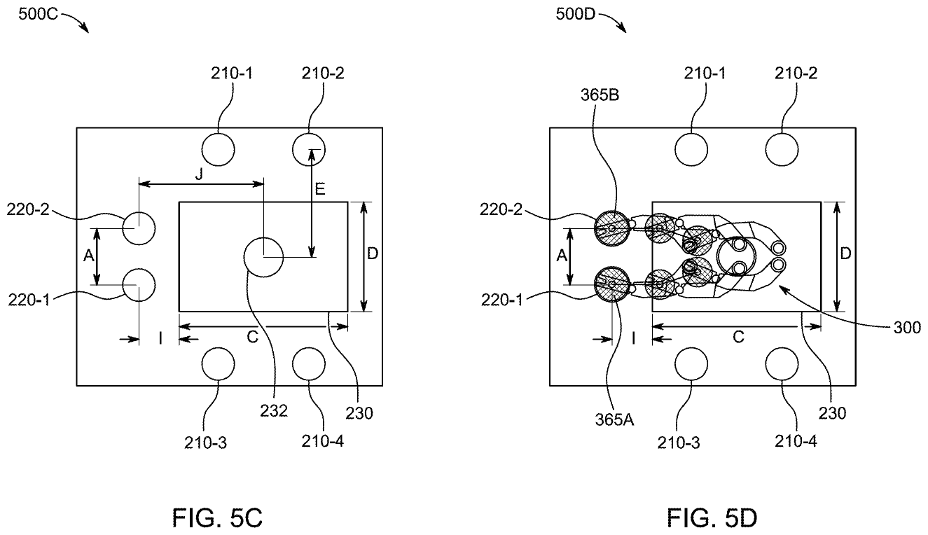

As will be described below with reference to FIGS. 5A-5D and FIGS. 10A-10H, a number of different arrangements can be provided to ensure that the retraction of the end effectors of the robot apparatus 232, after extension into the load lock chambers 220-1 and 220-2, sufficiently clears the walls of the rectangular mainframe 230. For example, the load lock chambers 220-1 and 220-2 can be independently accessed by respective load locks. As another example, to increase throughput relative to the independent access example, coordinated extension of a first end effector and a second end effector can achieved such that the second end effector lags behind the first end effector. That is, the first end effector extends into the load lock chamber 220-1 at a first time, and the second end effector extends into the load lock chamber 220-2 at a second time after the first time and prior to full retraction of the first end effector. As another example, the load lock chambers 220-1 and 220-2 can be positioned within the system 200 to achieve suitable load lock chamber access with respect to the first pitch A. As another example, a 4-theta drive mechanism can be used to enable a compressed motion envelope during load lock chamber extension (e.g., 2-theta for each end effector). Further details regarding the robot apparatus 232 will now be described below with reference to FIGS. 3A-X.

FIGS. 3A-3C illustrate views of a robot apparatus 300 according to some embodiments. For example, the robot apparatus 300 can be the robot apparatus 102 of FIG. 1 and/or the robot apparatus 232 of FIG. 2. More specifically, FIG. 3A is a perspective view of the robot apparatus 300, FIG. 3B is a top-down view of the robot apparatus 300 in a contracted or folded configuration, and FIG. 3C is a top-down view of the robot apparatus 300 in an extended configuration. In some embodiments, the robot apparatus 300 is a SCARA (Selective Compliance Assembly or Articulated Robot Arm) robot apparatus including at least two SCARA arms.

The robot apparatus 300 may include a base or body 314 optionally mounted on a linear track 316. The base 314 may be configured to move along the linear track 316. In one embodiment, the linear track 316 is a maglev track, that may include one or more stators, and the base 314 includes a mover that can be magnetically moved by the stator(s) of the linear track 316. Robot apparatus 300 may further include a lower shoulder 310A and an upper shoulder 310B configured to rotate about a rotational axis 315. For example, one or more motors (not shown) located in the base 314 may independently rotate the lower shoulder 310A and/or the upper shoulder 310B about the rotational axis 315. As shown, the upper shoulder may be positioned above the lower shoulder.

The robot apparatus 300 may further include a first arm 320A rotatably coupled to the lower shoulder 310A at a rotational axis 325 that is spaced away from the first rotational axis 315. First arm 320A may be configured to rotate about the rotational axis 325. For example, one or more motors (not shown) located in the base 314 may rotate the first arm 320A about the rotational axis 325.

The robot apparatus 300 may further include a second arm 320B rotatably coupled to the upper shoulder 310B at a rotational axis 335 that is spaced away from the rotational axis 315. Second arm 320B may be configured to rotate about the rotational axis 335. For example, one or more motors (not shown) located in the base 314 may rotate the second arm 320B about the rotational axis 335.

The robot apparatus 300 may further include a first forearm 330A rotatably coupled to the first arm 320A at a rotational axis 345 spaced from the rotational axis 325. The first forearm 330A may include a first bend in a first direction within a horizontal plane. The first forearm 330A may be configured to independently rotate about the rotational axis 345. For example, one or more motors (not shown) located in the base 314 may independently rotate the first forearm 330A about the rotational axis 345 for both the dual substrate handling mode and the single substrate handling mode.

The robot apparatus 300 may further include a second forearm 330B rotatably coupled to the second arm 320B at a rotational axis 355 spaced from the rotational axis 335. The second forearm 330B may include a second bend in a second direction within a horizontal plane, wherein the second direction is opposite the first direction. The second forearm may be configured to independently rotate about the rotational axis 355. For example, one or more motors (not shown) located in the base 314 may independently rotate the second forearm 330B about the rotational axis 355 for both the dual substrate handling mode and the single substrate handling mode.

The robot apparatus 300 may further include a first end effector 340A that is coupled (optionally rotatably) to the first forearm 330A, optionally through a first wrist 350A. The robot apparatus 300 may also include a second end effector 340B that is coupled (optionally rotatably) to the second forearm 330B optionally through a second wrist 350B. In some embodiments, the first end effector 340A and the second end effector 340B are coplanar.

As shown in FIG. 3B, the lower shoulder 310A, the upper shoulder 310B, the first arm 320A, the second arm 320B, the first forearm 330A, the second forearm 330B, optionally the first wrist 350A, optionally the second wrist 350B, the first end effector 340A, and the second end effector 340B form together a “W” shape when the robot apparatus 300 is in a contracted (or folded) configuration as shown in FIG. 3B. In some embodiments and as will be described below with reference to FIGS. 4A-4C, on full retraction, the first and second forearms and first and second end effectors fold inward towards each other, reducing a pitch between the end effectors.

As shown in FIG. 3C, the lower shoulder 310A, the upper shoulder 310B, the first arm 320A, the second arm 320B, the first forearm 330A, the second forearm 330B, optionally the first wrist 350A, optionally the second wrist 350B, the first end effector 340A, and the second end effector 340B form together a “V” shape when the robot apparatus 300 is in an extended configuration, suitable for reaching into load lock chambers (e.g., load lock chambers 220-1 and 220-2) or into processing chambers (e.g., processing chambers 210-1 and 210-2) in a dual substrate operating mode.

The lower shoulder 310A, the upper shoulder 310B, the first arm 320A, the second arm 320B, the first forearm 330A, the second forearm 330B, optionally the first wrist 350A, optionally the second wrist 350B, the first end effector 340A, and the second end effector 340B are configured to independently rotate about their corresponding rotational axis (e.g., about the rotational axis 315, about the rotational axis 325, about the rotational axis 335, about the rotational axis 345, about the rotational axis 355, and/or about additional rotational axis (if any)) for both, the dual substrate handling mode and the single substrate handling mode.

During operation, robot apparatus 300 may move along the linear track 316 to access various processing chambers and/or load lock chambers. In some embodiments, the robot apparatus 300 may have the retracted state as shown in FIG. 3B during movement along the linear track 316. In some embodiments, the robot 300 may have the retracted state described below with reference to FIG. 4C during movement along the linear track 316. Similarly, robot apparatus 300 may operate in single substrate handling mode, dual substrate handling mode, or a combination thereof to load and/or unload processing chambers and/or load lock chambers.

Operating in the dual substrate handling mode can include independently rotating the lower shoulder 310A, the upper shoulder 310B, the first arm 320A, the second arm 320B, the first forearm 330A, the second forearm 330B, optionally the first wrist 350A, optionally the second wrist 350B, the first end effector 340A, and the second end effector 340B, about the rotational axis 315, the rotational axis 325, the rotational axis 335, the rotational axis 345, and the rotational axis 355 to space the first end effector 350A from the second effector 350B by the first pitch A or by the second pitch B.

Operating in the single substrate handling mode can include independently rotating the lower shoulder 310A, the upper shoulder 310B, the first arm 320A, the second arm 320B, the first forearm 330A, the second forearm 330B, optionally the first wrist 350A, optionally the second wrist 350B, the first end effector 340A, and the second end effector 340B, about the rotational axis 315, the rotational axis 325, the rotational axis 335, the rotational axis 345, and the eighth rotational axis 355 to align the first end effector 340A and the second end effector 340B in a configuration suitable for one of the first end effector 340A or the second end effector 340B to access one load lock chamber or one processing chamber.

The first end effector 340A and the second end effector 340B can access adjacent chambers (e.g., processing chambers or load lock chambers) to retrieve substrates 365A and 365B, respectively. The robot apparatus 300 can operate to retrieve the substrates 365A and/or 365B in a single and/or dual substrate handling mode from adjacent load lock chambers or adjacent processing chambers. The substrates 365A and/or 365B can be transferred to different chambers (e.g., from the load lock chambers to adjacent processing chambers or from the processing chambers to adjacent load lock chambers).

One or more motors (not shown) located in the base 314 may independently rotate the lower shoulder 310A and the upper shoulder 310B about the rotational axis 315, the first arm 320A about the rotational axis 325, the second arm 320B about the rotational axis 335, the first forearm 330A about the rotational axis 345, and the second forearm 330B about the rotational axis 355 for both, the dual substrate handling mode and the single substrate handling mode.

For example, as shown, the forearms 320A and 320B and the arms 330A and 330B can have unequal lengths to enable variable pitch as a function of extension. A cam pulley design or a combination of a cam pulley design and one or more motors may be used to control one or more components of robot apparatus 300. For example, each of the forearms 320A and 320B may be driven independently by a respective motor. The arms 330A and 330B can each be coupled to a motor using at least one pulley (e.g., at least one non-circular pulley). The end effectors 340A and 340B can each be constrained by band drives including at least one pulley (e.g., at least one non-circular pulley) so that rotation of one of the forearms 320A and 320B can cause extension and retraction of the corresponding linkage along a straight line while the other linkage corresponding to the other one of the forearms 320A and 320B remains stationary. The use of non-circular pulleys can compensate for unequal link lengths (e.g., lower shoulder 310A does not have an equal length to forearm 320A, and upper shoulder 310B does not have an equal length to forearm 320B. Accordingly, the use of non-circular pulleys can enable the substrates 365A and 365B to move along respective linear radial paths with curved inward motion while maintaining the distance B during simultaneous extraction and retraction from adjacent processing chambers 210-1 and 210-2.

The operation of the robot apparatus 300 within a rectangular mainframe (e.g., the rectangular mainframe 230 of FIG. 2) for retrieving substrates in a single and/or dual substrate handling mode with respect to adjacent processing chambers will be further described below reference to FIGS. 4A-4C. The operation of the robot apparatus 300 within the rectangular mainframe for retrieving substrates in a single and/or dual substrate handling mode with respect to adjacent load lock chambers will be described below with reference to FIGS. 5A-5D.

FIGS. 4A-4C illustrate top-down views of a substrate processing system (“system”) and operation of the robot apparatus 300 of FIG. 3 housed within the rectangular mainframe 230 of FIG. 2 according to some embodiments. More specifically, FIG. 4A illustrates an extension operation 400A to retrieve (or place) the substrates 365A and 365B from the processing chambers 210-1 and 210-2 spaced apart by the pitch B, as described above with reference to FIGS. 2 and 3. FIG. 4B illustrates a retraction operation 400B to retract the substrates 365A and 365B (or empty end effectors) into the rectangular mainframe 230. As shown, the substrates 365A and 365B (or empty end effectors) are retracted into the rectangular mainframe 230 while maintaining an approximately or substantially constant distance B between the substrates 365A and 365B. In some embodiments, the distance B is not constant, but the distance between the centers of the substrates and/or end effectors is bounded by, or does not exceed, B. To ensure that the robot apparatus 300 and the substrates 365A and 365B are maintained within a sweep diameter 410 defined by the width of the rectangular mainframe 230 (e.g., width D described above with reference to FIG. 2), FIG. 4C illustrates a folding operation 400C in which the motion control mechanism of the robot apparatus 300 maneuvers the end effectors of the robot apparatus 300 (e.g., the first and second end effectors 340A and 340B of FIGS. 3A-3C) within the sweep diameter 410.

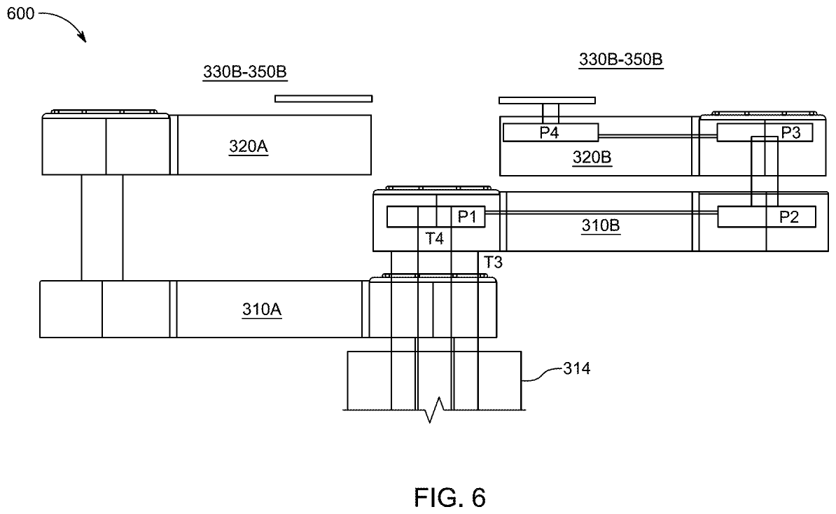

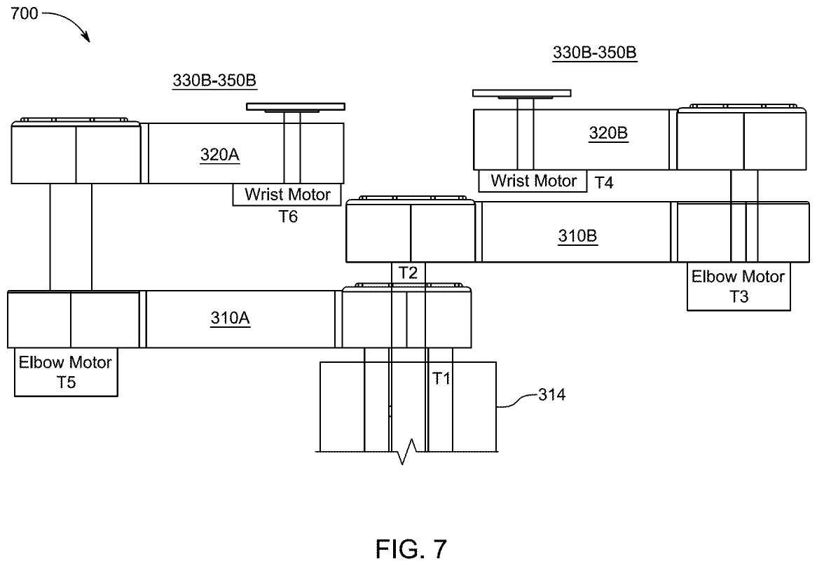

A motion control mechanism of the robot apparatus 300 maneuvers the end effectors of the robot apparatus 300 during the process illustrated by FIGS. 4A-4C. For example, the motion control mechanism can include a combination of motors and pulleys (e.g., non-circular pulleys), as described above with reference to FIG. 3. Further details regarding the motion control mechanism will be described below with reference to FIGS. 6-7.

Although not shown in FIGS. 4A-4C, robot apparatus 300 can also access a single load processing chamber 210-1 or 210-2 to retrieve a single substrate 365A or 365B. This may be useful to continue operation of the system when, for example, one of the processing chambers 210-1 or 210-2 is out of repair.

FIGS. 5A-5D illustrate top-down views of various substrate processing systems (“systems”) including the robot apparatus 300 of FIG. 3 housed within the rectangular mainframe 230 of FIG. 2 according to some embodiments. As shown in FIGS. 5A-5D, the load lock chamber 220-1 and the rectangular mainframe 230 can be separated by a distance “I” as measured between the centers of the load lock chamber 220-1 and the rectangular mainframe 230. In some embodiments, the distance I is in a range of about 12 inches to about 20 inches. In some embodiments, the distance I is in a range of about 14 inches to about 18 inches. In some embodiments, the distance I is about 16 inches.

FIG. 5A illustrates independent load lock chamber access with respect to load lock chambers 220-1 and 220-2 separated by the first pitch A, as described above with reference to FIG. 2. More specifically, each of the end effectors 340A and 340B of the robot apparatus 300 (as described above with reference to FIG. 3) retrieves one of the substrates 365A and 365B independently. In this illustrative example, the robot apparatus 300 first extends the end effector 340A into the load lock chamber 220-1 to retrieve the substrate 365A, and then retracts the end effector 340A within the rectangular mainframe 230. After retracting the end effector 340A within the rectangular mainframe 230, the robot apparatus 300 then extends the end effector 340B into the load lock chamber 220-2 to retrieve the substrate 365B, and then retracts the end effector 340B within the rectangular mainframe 230.

FIG. 5B illustrates a top-down view of a substrate processing system (“system”) 500B according to some embodiments. More specifically, the system 500B illustrates coordinated load lock chamber access with respect to load lock chambers 220-1 and 220-2 separated by the first pitch A, as described above with reference to FIG. 2. More specifically, instead of independently accessing the load lock chambers with its end effectors 340A and 340B, the robot apparatus 300 coordinates the extension of its end effectors 340A and 340B in a manner that enables the robot apparatus 300 to clear the width D of the rectangular mainframe 230 and avoid collision between end effectors and/or held substrates during extension and/or retraction, in which one of the end effectors lags behind the other end effector during the extension and/or retraction process. In this illustrative example, the robot apparatus 300 initiates retrieval of the substrate 365A by extending the end effector 340A into the load lock chamber 220-1. After a certain amount of time has passed (“lag time”), the robot apparatus 300 then initiates retrieval of the substrate 365B by extending the end effector 340B into the load lock chamber 220-2. The lag time can be chosen to be the smallest amount of time that can maximize throughput while avoiding a collision between the robot apparatus 300 and the rectangular mainframe 230 and/or other end effector. Additionally, there can be multiple speed settings with respect to the speed at which extension and retraction is performed. As an illustrative example, a “slow speed” setting can perform extension in about 2 seconds, and a “fast speed” setting can perform extension in about 1 second. In these examples, the lag time for the slow speed setting can be chosen to be about 1 second and the lag time for the fast speed setting can be chosen to be about 0.5 second.

FIG. 5C illustrates a top-down view of a substrate processing system (“system”) 500C according to some embodiments. More specifically, the system 500C is based on the system 200 of FIG. 2. In particular, the system 500C shows that the load lock chamber 220-2 and the robot apparatus 232 can be separated by a distance “J” as measured between the centers of the load lock chamber 220-2 and the robot apparatus 230. The distance J is chosen to compensate for the narrower pitch A between the load lock chambers 220-1 and 220-2 as a result of the rectangular shape of mainframe 230. In some embodiments, the distance J is in a range of about 35 inches to about 65 inches. In some embodiments, the distance J is in a range of about 40 inches to about 60 inches. In some embodiments, the distance J is about 50 inches.

FIG. 5D illustrates a top-down view of a substrate processing system (“system”) 500D according to some embodiments. More specifically, the system 500D illustrates an example of the robot apparatus 300 being configured to enable individual control of rotation, extraction and retraction and/or variable pitch access with respect to the compressed motion envelope defined by width D of the rectangular mainframe 230. For example, the robot apparatus 300 can simultaneously extract and retract the substrates 365A and 365B from the respective load lock chambers 220-1 and 220-2.

In some embodiments, as will be described in further detail below with reference to FIG. 6, the robot apparatus 300 can be operated with a 4-theta motion driving assembly (2-theta for each of the end effectors). In some embodiments, as will be described in further detail with reference to FIG. 7, the robot apparatus 300 can be operated with a 2-theta motion driving assembly for base links, and motors at the elbow and wrist (e.g., a 6 motor solution).

FIG. 6 illustrates an example robot apparatus 600 having a motion driving assembly according to some embodiments. More specifically, the motion driving assembly is a 4-theta motion driving assembly, with 2-theta for each of the end effectors. For example, with respect to the “upper shoulder side” of the robot apparatus 600, the robot apparatus 600 can include elbow motors “T3” and “T5” at respective elbow joints connecting respective links, and wrist motors “T4” and “T6” connecting respective links. T3 rotates upper shoulder 310B, T4 rotates pulley “P1”, pulley “P2” is coupled to pulley P1 and rotates pulley “P3” and arm 320B, pulley “P4” is coupled to pulley P3 and rotates the combination of forearm 330B, end effector 340B and (optional) wrist 350B. A similar motion driving assembly can be used to enable motion with respect to the “lower shoulder side” of the robot apparatus 600.

FIG. 7 illustrates an example robot apparatus 700 having a motion driving assembly according to some embodiments. More specifically, FIG. 7 illustrates a 6 motor solution with motors at various joints. For example, the robot apparatus 700 can include a number of motors “T1” through “T6” each at a respective joint. For example, motor T1 be at the joint connecting the body 314 and a first end of the lower shoulder 310A, motor T2 can be at the joint connecting the first end of the lower shoulder 310A and a first end of the upper shoulder 310B, motor T3 can be at the elbow joint connecting a second end of the upper shoulder 310B and a first end of the arm 320B (“elbow motor”), motor T4 can be at the wrist joint connecting a second end of the arm 320B and the combination of forearm 330B, end effector 340B and (optional) wrist 350B (“wrist motor”), motor T5 can be at the elbow joint connecting a second end of the lower shoulder 310B and a first end of the arm 320A (“elbow motor”), and motor T6 can be at the wrist joint connecting a second end of the arm 320A and the combination of forearm 330A, end effector 340A and (optional) wrist 350A (“wrist motor”).

FIGS. 8A-8B illustrate a robot apparatus 800 according to some embodiments. More specifically, FIG. 8A illustrates a perspective view of the robot apparatus 800 and FIG. 8B illustrates a top-down view of the robot apparatus 800. For example, the robot apparatus 800 can be the robot apparatus 102 of FIG. 1 and/or the robot apparatus 232 of FIG. 2. The robot apparatus 800 may include a lower arm 810A and an upper arm 810B configured to rotate about a rotational axis 820. More specifically, the upper arm 810B may be rotatably coupled to the lower arm 810 at the rotational axis 820.

The robot apparatus 800 may further include a blade 830A rotatably coupled to the lower arm 810A at, and configured to rotate about, a rotational axis 840A that is spaced away from the rotational axis 820. The blade 830A can include at least one end effector 835A configured to transport a substrate (e.g., extend into a processing chamber or load lock chamber to retrieve a substrate). The robot apparatus 800 may further include a blade 830B rotatably coupled to the upper arm 810B at, and configured to rotate about, a rotational axis 840B that is spaced away from the rotational axis 820. The blade 830B can include at least one end effector 835B configured to transport a substrate (e.g., extend into a processing chamber or a load lock chamber to retrieve a substrate). In some embodiments, the blade 830A and the blade 830B are each positioned with respect to a common substrate transfer plane (e.g., blades 830A and 830B are coplanar).

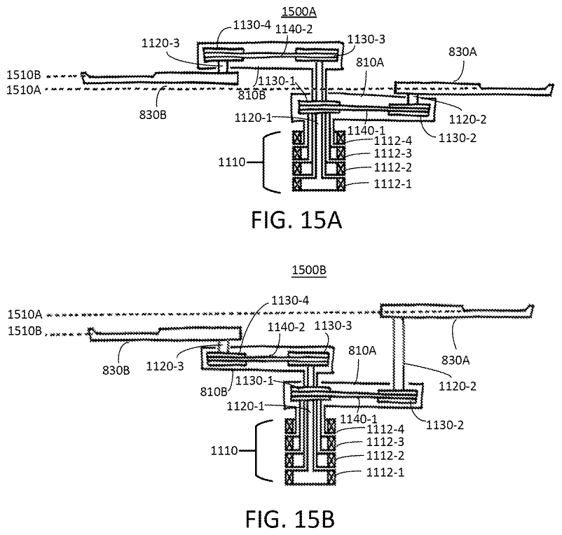

In some embodiments, the blade 830A is positioned with respect to a first substrate transfer plane, and the blade 830B is positioned with respect to a second substrate transfer plane vertically offset from the first substrate transfer plane (e.g., blades 830A and 830B are non-coplanar or vertically offset). Further details regarding these embodiments are described below with reference to FIGS. 15A-17.

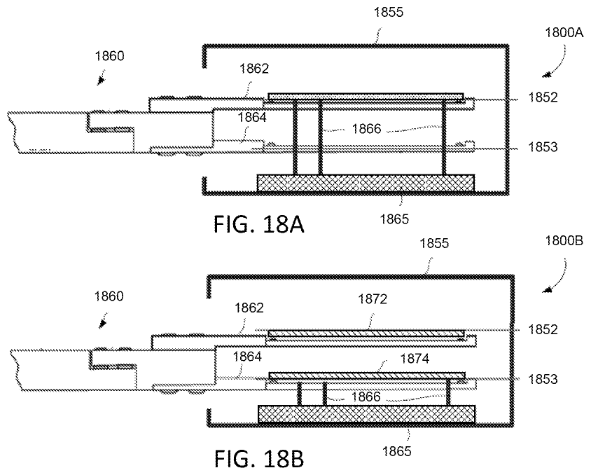

In some embodiments, blade 830A and blade 830B each include a plurality of end effectors. For example, blade 830A and blade 830B can each include a pair of end effectors. Further details regarding these embodiments are described below with reference to FIGS. 18A-18B.

A set of motors, operatively coupled to a controller (e.g., the controller 142 of FIG. 1), may be configured to rotate the lower arm 810A, the upper arm 810B, the blade 830A and/or the blade 830B about their respective rotational axes 820, 840A and 840B for both the dual substrate handling mode and the single substrate handling mode. For example, the set of motors can be located in a base of the robot apparatus 800 (not shown) to independently rotate the lower arm 810A, the upper arm 810B, the blade 830A and/or the blade 830B about the rotational axis 820. As another example, the robot apparatus 800 can include a distributed motor system in which each motor of the set of motors is located at respective linkages of the robot apparatus 800.

As shown in FIG. 8B, the lower arm 810A can have a length “L1” and the blade 830A can have a length “L2”. The length L1 can be defined from the center of the rotational axis 820 to the center of the rotational axis 840A. The length L2 can be defined from the center of the rotational axis 840 to the center of the blade 835A. The upper arm 810B can similarly have the length L1 and the blade 830B can similarly have the length L2.

In some embodiments, the length L1 is in a range of about 10 inches to about 25 inches. In some embodiments, the length L1 is in a range of about 15 inches to about 20 inches. In some embodiments, the length L1 is about 19 inches. In some embodiments, the length L2 is in a range of about 20 inches to about 45 inches. In some embodiments, the length L2 is in a range of about 30 inches to about 40 inches. In some embodiments, the length L2 is about 36 inches. Other distances for the length L1 and/or the length L2 may also be possible.

The lengths L1 and L2 can be chosen in accordance with the dimensions of a transfer chamber in which the robot apparatus 800 is housed. For example, the transfer chamber may be the transfer chamber 106 of FIG. 1 and/or the transfer chamber 230 of FIG. 2. Illustratively, if the ratio of the length C to the width D (i.e., C:D) is about 1.545 (as described above with reference to FIG. 2), then the ratio of L1 to L2 (i.e., L1:L2) can be about 0.52.

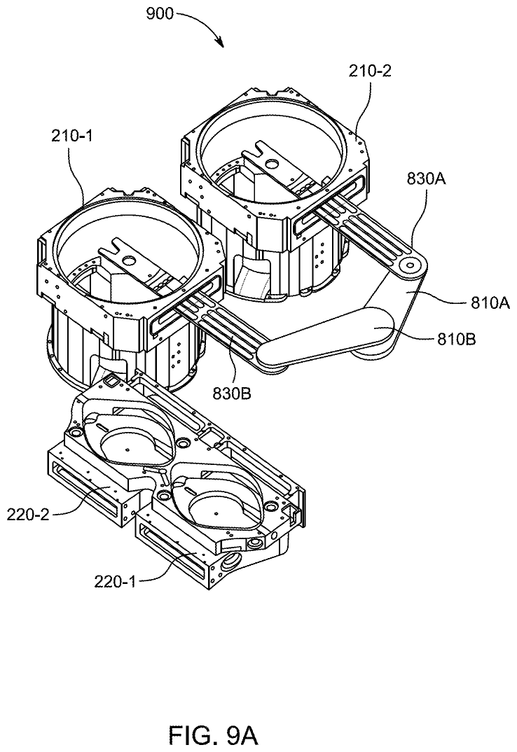

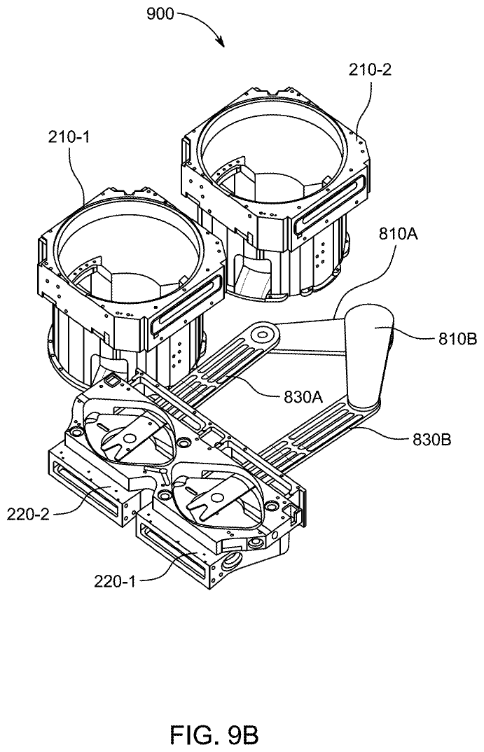

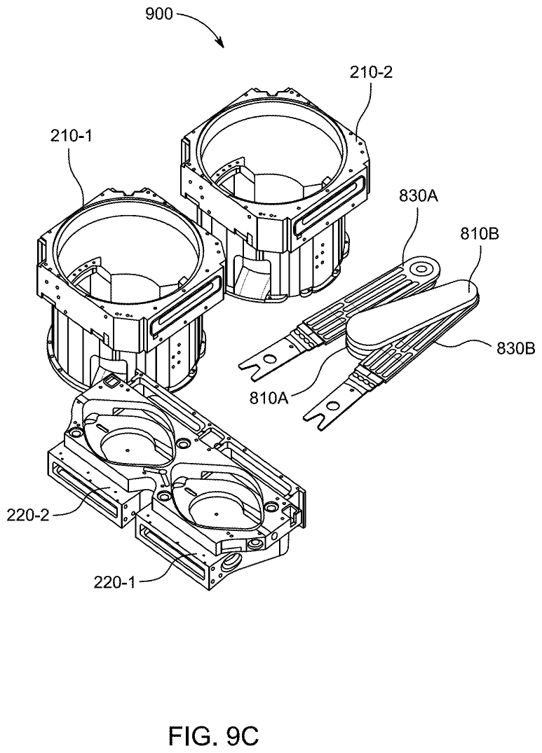

FIGS. 9A-9C illustrate perspective views of the robot apparatus 800 housed within a substrate processing system 900 according to some embodiments. The system 900 can be included in the system 100 of FIG. 1 and/or the system 200 of FIG. 2. More specifically, FIG. 9A is a perspective view of the robot apparatus 800 in a first extended configuration during which the blades 830A and 830B are extended into respective processing chambers 210-1 and 210-2, FIG. 9B is a perspective view of the robot apparatus 800 in a second extended configuration during which the blades 830A and 830B are extended into respective load lock chambers 220-1 and 220-2, and FIG. 3C is a perspective view of the robot apparatus 800 in a contracted or folded configuration. As shown in FIG. 3C, the blades 830A and 830B are folded or retracted inward within a sweep diameter defined by a width of the rectangular mainframe, as described in further detail above with reference to FIGS. 1-2.

FIGS. 10A-10H illustrate top-down views of a substrate processing system (“system”) and operation of the robot apparatus 800 of FIGS. 8A-8B housed within the rectangular mainframe 230 of FIG. 2 according to some embodiments. More specifically, FIG. 10A illustrates an initial operation 1000A in which a substrate 1010-1 is located within the load lock chamber 220-1 and a substrate 1010-2 is located within the load lock chamber 220-2. The substrates 1010-1 and 1010-2 are spaced apart by the pitch A, as described above with reference to FIG. 2.

FIG. 10B illustrates an extension operation 1000B to retrieve the substrates 1010-1 and 1010-2 from the load lock chambers 220-1 and 220-2 spaced apart by the pitch B. In this illustrative embodiment, both end effectors of the robot apparatus (e.g., blades 830A and 830B of FIGS. 8A-8B), are extended simultaneously into respective ones of the load lock chambers 220-1 and 220-2. The arms of the robot apparatus 800 (e.g., lower arm 810A and upper arm 810B) can each have a length L1 and the end effectors of the robot apparatus can each have a length L2, as described above with reference to FIG. 8B. Furthermore, upon extension into the load lock chambers 220-1 and 220-2, each end effector can have an angle of rotation having a magnitude “a”. For example, a for the end effector extending into the load lock chamber 220-1 can be the magnitude of a clockwise angle of rotation about its respective rotation axis (e.g., rotation axis 840B of FIG. 8A), and a for the end effector extending into the load lock chamber 220-2 can be the magnitude of a counterclockwise angle of rotation about its respective rotation axis (e.g., rotation axis 840A of FIG. 8A). In some embodiments, a is in a range of about 1° to about 5°. In some embodiments, a is in a range of about 2° to about 4°. In some embodiments, al is about 3°.

FIG. 10C illustrates a retraction and folding operation 1000C to retract the substrates 1010-1 and 1010-2 into the rectangular mainframe 230, and fold the end effectors inward within a sweep diameter 1020 defined by the width of the rectangular mainframe 230 (e.g., width D described above with reference to FIG. 2). As a result of the folding, the substrates 1010-1 and 1010-2 are maintained within the sweep diameter 1020. For example, the substrates 1010-1 and 1010-2 are spaced apart by a new pitch A′. The pitch A′ is defined by sweep diameter 1020. In some embodiments, the pitch A′ is in a range of about 5 inches to about 20 inches. In some embodiments, the pitch A′ is in a range of about 10 inches to about 15 inches. In some embodiments, the pitch A′ is about 12 inches. FIG. 10D illustrates an extension operation 1000D to place the substrates 1010-1 and 1010-2 into the processing chambers 210-1 and 210-2, respectively.

FIG. 10E illustrates a post-processing operation 1000E after the substrates 1010-1 and 1010-2 have been processed within their respective processing chambers 210-1 and 210-2. FIG. 10F illustrates an extension and retraction operation 1000F to retrieve the substrates 1010-1 and 1010-2 from the processing chambers 210-1 and 210-2 spaced apart by the pitch B. In this illustrative embodiment, both end effectors of the robot apparatus are extended simultaneously into respective ones of the processing chambers 210-1 and 210-2, and are retracted simultaneously. As shown, the substrates 1010-1 and 1010-2 are retracted into the rectangular mainframe 230 while maintaining an approximately or substantially constant distance B between the substrates 1010-1 and 1010-2. In some embodiments, the distance B is not constant, but the distance between the centers of the substrates and/or end effectors is bounded by, or does not exceed, B.

FIG. 10G illustrates a folding and rotation operation 1000G to fold the end effectors inward within a sweep diameter 1020 defined by the width of the rectangular mainframe 230 (e.g., width D described above with reference to FIG. 2), and rotate the robot apparatus 800 to place the end effectors in alignment with the load lock chambers 220-1 and 220-2. As a result of the folding, the substrates 1010-1 and 1010-2 are maintained within the sweep diameter 1020 (not shown in FIG. 10G). For example, the substrates 1010-1 and 1010-2 are spaced apart by the pitch A′. FIG. 10H illustrates an extension operation 1000D to place the substrates 1010-1 and 1010-2 into the load lock chambers 210-1 and 210-2, respectively.

The process shown in FIGS. 10A-10H can have a total two substrate cycle time of less than 50 seconds. This can correspond to a throughput greater than about 129 substrates per hour. For example, the process shown in FIGS. 10A-10H can have a total two substrate cycle of time about 34 seconds, and a throughout of about 211 substrates per hour.

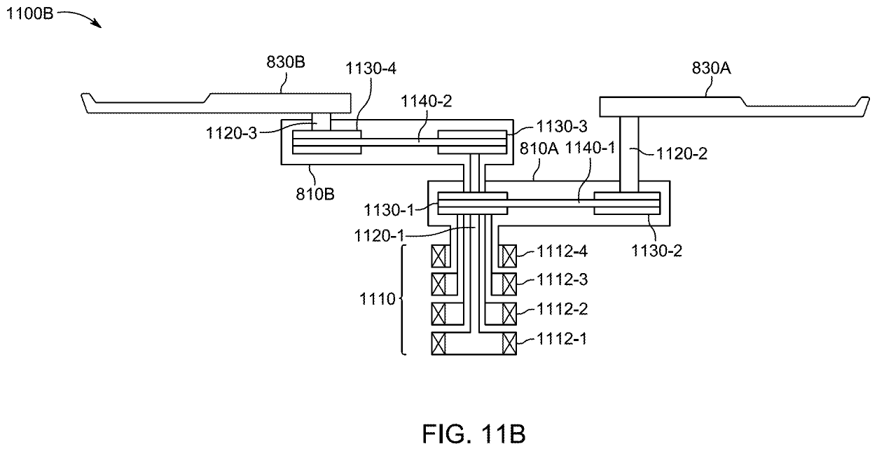

A motion control mechanism of the robot apparatus 800 maneuvers the end effectors of the robot apparatus 800 during the process illustrated by FIGS. 10A-10H. For example, the motion control mechanism can include a combination of motors and pulleys (e.g., non-circular pulleys), as described above with reference to FIG. 3. Further details regarding the motion control mechanism will be described below with reference to FIGS. 11A-13.

Although not shown in FIGS. 10A-10H, robot apparatus 800 can also access a single load processing chamber 210-1 or 210-2 to retrieve a single substrate 1010-1 or 1010-2. This may be useful to continue operation of the system when, for example, one of the processing chambers 210-1 or 210-2 is out of repair.

FIG. 11A illustrates an example robot apparatus 1100A having a motion driving assembly according to some embodiments. More specifically, robot apparatus 1100A includes a 4-axis drive mechanism. For example, robot apparatus 1100A can include a 4-theta drive mechanism (e.g., 2-theta for each end effector). As shown, robot apparatus 1100A includes arms 810A and 810B and blades 830A and 830B as described above with reference to FIGS. 8A-8B. Blades 830A and 830B can be substantially co-planar. Robot apparatus 1110A further includes base 1100 having a number of motors including motors 1112-1 through 1112-4. Robot apparatus 1100A further includes a number of links 1120-1 through 1120-3. Robot apparatus 1100A further includes a number of pulleys 1130-1 through 1130-4, where pulleys 1130-1 and 1130-2 are located within arm 810A and pulleys 1130-3 and 1130-4 are located within arm 810B. Robot apparatus 1100A further includes a number of bands 1140-1 and 1140-2, where band 1140-1 is attached to pulleys 1130-1 and 1130-2, and band 1140-2 is attached to pulleys 1130-3 and 1130-4. More specifically, link 1120-1 extends from base 1110 to pulley 1130-3 through pulley 1130-1, link 1120-2 connects pulley 1130-2 to blade 830A and link 1120-3 connects pulley 1130-4 to blade 830B. Links 1120-2 and 1220-3 can also be referred to as “elbows” or “joints.”

The operation of motors 1112-1 through 1112-4 can be independently controlled by a controller (e.g., controller 142 of FIG. 1) to cause robot apparatus 1100A to operate in accordance with the process described above with reference to FIGS. 10A-10H. For example, motor 1112-1 can cause blade 830B to rotate about axis 840B, motor 1112-2 can cause arm 810B to rotate about axis 820, motor 1112-3 can cause blade 830A to rotate about axis 840A, and motor 1112-4 can cause arm 810A to rotate about axis 820. Thus, robot apparatus 1100A can operate in a dual substrate handling mode or a single substrate handling mode.

FIG. 11B illustrates an example robot apparatus 1100B having a motion driving assembly according to some embodiments. Robot apparatus 1100B is similar to the robot apparatus 1100A (e.g., includes a similar 4-axis drive mechanism), except that blade 830B is located above arm 810B (instead of below arm 810B as shown in FIG. 11A. In other words, link 1120-3 is disposed on top of pulley 1130-4 (instead of below pulley 1130-4 as shown in FIG. 11A). To account for this, the length of links 1120-2 is increased so that blades 830A and 830B are substantially co-planar. Motors 1112-1 through motors 1112-4 can operate in a similar manner as described above in FIG. 11A. Thus, robot apparatus 1100B can operate in a dual substrate handling mode or a single substrate handling mode.

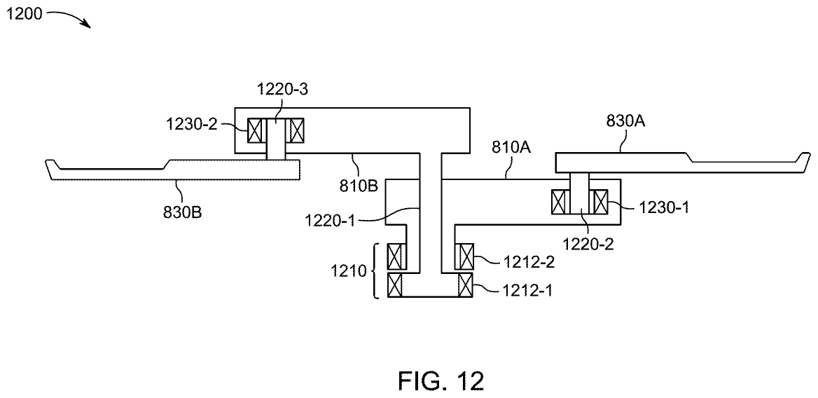

FIG. 12 illustrates an example robot apparatus 1200 having a motion driving assembly according to some embodiments. More specifically, robot apparatus 1200 has a distributed motor drive mechanism. As shown, robot apparatus 1200 includes arms 810A and 810B and blades 830A and 830B as described above with reference to FIGS. 8A-8B. Robot apparatus 1200 further includes base 1210 having a number of motors including motors 1212-1 and 1212-2. Robot apparatus 1200 further includes a number of links 1220-1 through 1220-3. Instead of pulleys, robot apparatus 1200 further includes motor 1230-1 embedded within arm 810A and operatively coupled to link 1220-2 and motor 1230-2 embedded within arm 810B operatively coupled to link 1220-3. More specifically, link 1220-1 connects base 1210 to arm 810B, link 1120-2 connects motor 1230-1 to blade 830A and link 1220-3 connects motor 1230-2 to blade 830B. Links 1220-2 and 1220-3 can also be referred to as “elbows” or “joints.” Accordingly, each motor is distributed about respective links, instead of being centrally located in a base.

The operation of motors 1212-1, 1212-2, 1230-1 and 1230-2 can be independently controlled by a controller (e.g., controller 142 of FIG. 1) to cause robot apparatus 1200 to operate in accordance with the process described above with reference to FIGS. 10A-10H. For example, motor 1212-1 cause arm 810B to rotate about axis 820, motor 1212-2 can cause arm 810A to rotate about axis 820, motor 1230-1 can cause blade 830A to rotate about axis 840A, and motor 1230-2 can cause blade 830B to rotate about axis 840B. Thus, robot apparatus 1200 can operate in a dual substrate handling mode or a single substrate handling mode.

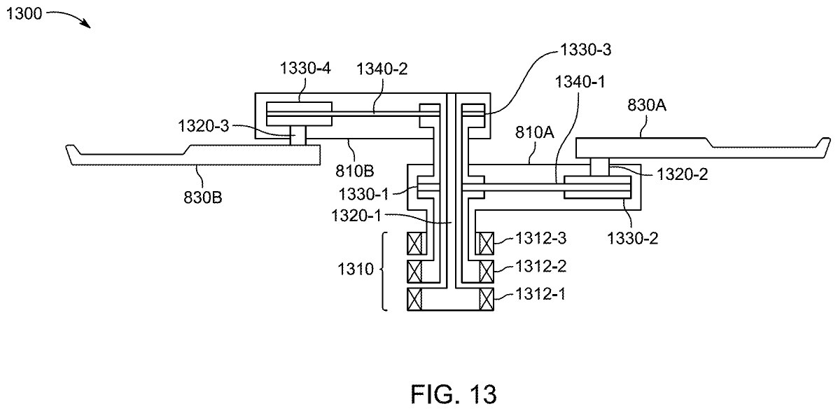

FIG. 13 illustrates an example robot apparatus 1300 having a motion driving assembly according to some embodiments. More specifically, robot apparatus 1300 includes a 3-axis drive mechanism. For example, robot apparatus 1300 can include a 3-theta drive mechanism.

As shown, robot apparatus 1300 includes arms 810A and 810B and blades 830A and 830B as described above with reference to FIGS. 8A-8B. Robot apparatus 1300 further includes base 1310 having a number of motors including motors 1312-1 through 1312-3. Robot apparatus 1300 further includes a number of links 1320-1 through 1320-3. Robot apparatus 1300 further includes a number of pulleys 1330-1 through 1330-4, where pulleys 1330-1 and 1330-2 are located within arm 810A and pulleys 1330-3 and 1330-4 are located within arm 810B. Robot apparatus 1300 further includes a number of bands 1340-1 and 1340-2, where band 1340-1 is attached to pulleys 1330-1 and 1330-2, and band 1340-2 is attached to pulleys 1330-3 and 1330-4. More specifically, link 1320-1 extends from base 1310 to an upper surface of arm 810B through pulleys 1330-1 and 1330-3, link 1320-2 connects pulley 1330-2 to blade 830A and link 1320-3 connects pulley 1330-4 to blade 830B. Links 1320-2 and 1320-3 can also be referred to as “elbows” or “joints.”

The operation of motors 1312-1 through 1312-3 can be independently controlled by a controller (e.g., controller 142 of FIG. 1) to cause robot apparatus 1300 to operate in accordance with the process described above with reference to FIGS. 10A-10H. For example, motor 1312-1 can cause arm 810B to rotate about axis 820, motor 1312-3 can cause arm 810A to rotate about axis 820, and motor 1312-2 can cause blade 830A to rotate about axis 840A and cause blade 830B to rotate about axis 840B. For example, motor 1312-2 can cause simultaneous rotation of blade 830A and blade 830B. Thus, since the rotation of blades 830A and 830B may be simultaneously controlled, robot apparatus 1300 may only be able to operate dual substrate handling mode.

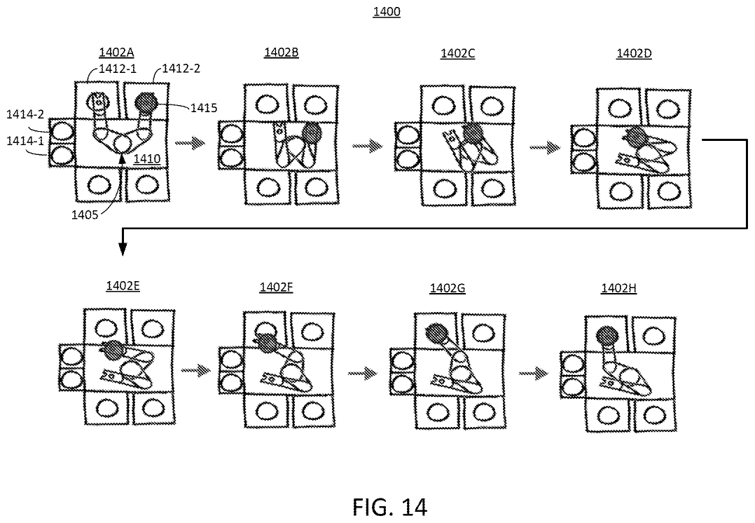

FIG. 14 illustrates a diagram 1400 showing top-down view of operations of robot apparatus 1405 housed within rectangular mainframe 1410, according to some embodiments. In some embodiments, robot apparatus 1405 corresponds to robot apparatus 1100A of FIG. 11A, robot apparatus 1100B of FIG. 11B, robot apparatus 1200 of FIG. 12, or robot apparatus 1300 of FIG. 13. Rectangular mainframe 1410 can include first processing chamber 1412-1, second processing chamber 1412-2, first load lock chamber 1412-1 and second load lock chamber 1412-2. First processing chamber 1412-1 and second processing chamber 1412-2 are separated by a first pitch. As further shown, substrate 1415 is located within second processing chamber 1412-2.

During operation 1402A, robot apparatus 1405 extends each end effector of a pair of end effectors into a respective one of first processing chamber 1412-1 and second processing chamber 1412-2. During operation 1402B, robot apparatus 1405 retracts each end effector into rectangular mainframe 1410 while maintaining a distance between each end effector that is bounded by the first pitch throughout a retraction process. The retraction removes substrate 1415 from second processing chamber 1412-2, which is being carried by one of the end effectors. As further shown during operation 1402B, robot apparatus 1405 folds each end effector inward within a sweep diameter defined by a width of rectangular mainframe 1410. During operations 1402C-1402D, robot apparatus 1405 incrementally rotates toward first processing chamber 1412-1. During operations 1402E-1402G, robot apparatus 1405 incrementally extends the end effector carrying substrate 1415 into first processing chamber 1412-1. During operation 1402H, robot apparatus 1405 rotates counterclockwise such that the end effector carrying substrate 1415 is approximately perpendicular with respect to the length of rectangular mainframe 1410. This can enable robot apparatus 1405 to retract the end effector carrying substrate 1415 after completing the transfer of substrate 1415 from second processing chamber 1412-2 to first processing chamber 1412-1. Accordingly, the illustrative embodiment of FIG. 14 shows an example of left/right swap of a single substrate 1415 between processing chambers 1412-2 and 1412-1.

FIG. 15A illustrates an example robot apparatus 1500A having motion driving assemblies according to some embodiments. More specifically, robot apparatus 1500A includes a 4-axis drive mechanism. For example, robot apparatus 1500A can include a 4-theta drive mechanism (e.g., 2-theta for each end effector). As shown, robot apparatus 1500A includes arms 810A and 810B and blades 830A and 830B as described above with reference to FIGS. 8A-8B. Blades 830A and 830B can be substantially co-planar. Robot apparatus 1500A further includes base 1100 having a number of motors including motors 1112-1 through 1112-4. Robot apparatus 1500A further includes a number of links 1120-1 through 1120-3. Robot apparatus 1500A further includes a number of pulleys 1130-1 through 1130-4, where pulleys 1130-1 and 1130-2 are located within arm 810A and pulleys 1130-3 and 1130-4 are located within arm 810B. Robot apparatus 1500A further includes a number of bands 1140-1 and 1140-2, where band 1140-1 is attached to pulleys 1130-1 and 1130-2, and band 1140-2 is attached to pulleys 1130-3 and 1130-4. More specifically, link 1120-1 extends from base 1110 to pulley 1130-3 through pulley 1130-1, link 1120-2 connects pulley 1130-2 to blade 830A and link 1120-3 connects pulley 1130-4 to blade 830B. Links 1120-2 and 1220-3 can also be referred to as “elbows” or “joints.”

As further shown, blades 830A and 830B can be vertically offset. For example, blade 830A can be positioned with respect to substrate transfer plane 1510A and blade 830B can be positioned with respect to substrate transfer plane 1510B. Accordingly, in this example, substrate transfer plane 1510A is a lower substrate transfer plane and substrate transfer plane 1510B is an upper substrate transfer plane.

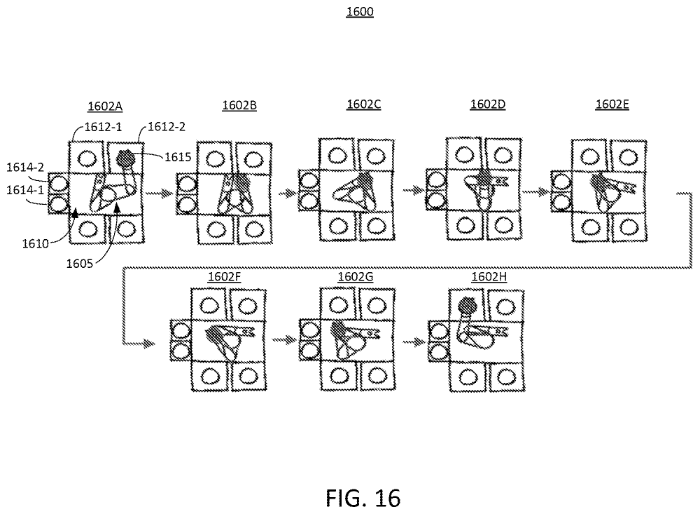

The operation of motors 1112-1 through 1112-4 can be independently controlled by a controller (e.g., controller 142 of FIG. 1) to cause robot apparatus 1500A to operate in accordance with the processes described above with reference to FIGS. 10A-10H, and/or below with reference to FIGS. 14, 16 and/or 17. For example, motor 1112-1 can cause blade 830B to rotate about axis 840B, motor 1112-2 can cause arm 810B to rotate about axis 820, motor 1112-3 can cause blade 830A to rotate about axis 840A, and motor 1112-4 can cause arm 810A to rotate about axis 820. Thus, robot apparatus 1500A can operate in a dual substrate handling mode or a single substrate handling mode.

FIG. 15B illustrates an example robot apparatus 1500B having a motion driving assembly according to some embodiments. More specifically, robot apparatus 1500B includes a 4-axis drive mechanism. For example, robot apparatus 1500B can include a 4-theta drive mechanism (e.g., 2-theta for each end effector). As shown, robot apparatus 1500B includes arms 810A and 810B and blades 830A and 830B as described above with reference to FIGS. 8A-8B. Blades 830A and 830B can be substantially co-planar. Robot apparatus 1500B further includes base 1100 have a number of motors including motors 1112-1 through 1112-4. Robot apparatus 1500B further includes a number of links 1120-1 through 1120-3. Robot apparatus 1500B further includes a number of pulleys 1130-1 through 1130-4, where pulleys 1130-1 and 1130-2 are located within arm 810A and pulleys 1130-3 and 1130-4 are located within arm 810B. Robot apparatus 1500B further includes a number of bands 1140-1 and 1140-2, where band 1140-1 is attached to pulleys 1130-1 and 1130-2, and band 1140-2 is attached to pulleys 1130-3 and 1130-4. More specifically, link 1120-1 extends from base 1110 to pulley 1130-3 through pulley 1130-1, link 1120-2 connects pulley 1130-2 to blade 830A and link 1120-3 connects pulley 1130-4 to blade 830B. Links 1120-2 and 1220-3 can also be referred to as “elbows” or “joints.”

As further shown, blades 830A and 830B can be vertically offset. For example, blade 830A can be positioned with respect to substrate transfer plane 1510A and blade 830B can be positioned with respect to substrate transfer plane 1510B. Accordingly, in this example, substrate transfer plane 1510A is an upper substrate transfer plane and substrate transfer plane 1510B is a lower substrate transfer plane.

The operation of motors 1112-1 through 1112-4 can be independently controlled by a controller (e.g., controller 142 of FIG. 1) to cause robot apparatus 1500B to operate in accordance with the processes described above with reference to FIGS. 10A-10H, and/or below with reference to FIGS. 14, 16 and/or 17. For example, motor 1112-1 can cause blade 830B to rotate about axis 840B, motor 1112-2 can cause arm 810B to rotate about axis 820, motor 1112-3 can cause blade 830A to rotate about axis 840A, and motor 1112-4 can cause arm 810A to rotate about axis 820. Thus, robot apparatus 1500B can operate in a dual substrate handling mode or a single substrate handling mode.

FIG. 16 illustrates a diagram 1600 showing top-down view of operations of robot apparatus 1605 housed within rectangular mainframe 1610, according to some embodiments. In some embodiments, robot apparatus 1605 corresponds to robot apparatus 1500A of FIG. 15A or robot apparatus 1500B of FIG. 15B. Rectangular mainframe 1610 can include first processing chamber 1612-1, second processing chamber 1612-2, first load lock chamber 1612-1 and second load lock chamber 1612-2. First processing chamber 1612-1 and second processing chamber 1612-2 are separated by a first pitch. As further shown, substrate 1615 is located within second processing chamber 1612-2.

During operation 1602A, robot apparatus 1605 extends an effector of a pair of end effectors into second processing chamber 1612-2. During operation 1602B, robot apparatus 1605 retracts the end effector into rectangular mainframe 1610 to remove substrate 1615 from second processing chamber 1612-2. As further shown during operation 1602B, robot apparatus 1605 folds each end effector inward within a sweep diameter defined by a width of rectangular mainframe 1610. During operations 1602C-1602G, robot apparatus 1605 incrementally rotates and maneuvers the pair of end effectors, such that the end effector carrying substrate 1615 is approximately perpendicular with respect to the length of rectangular mainframe 1610. During operation 1602H, robot apparatus 1605 can extend the end effector carrying substrate 1615 into first processing chamber 1612-1. This can enable robot apparatus 1605 to retract the end effector carrying substrate 1615 after completing the transfer of substrate 1615 from second processing chamber 1412-2 to first processing chamber 1412-1. Accordingly, the illustrative embodiment of FIG. 16 shows an example of left/right swap of a single substrate 1615 between processing chambers 1615-2 and 1615-1 enabled by allowing substrate 1615 to be transported on separate (upper and lower) substrate transfer planes (e.g., substrate transfer planes 1510A and 1510B of FIG. 15A or 15B).

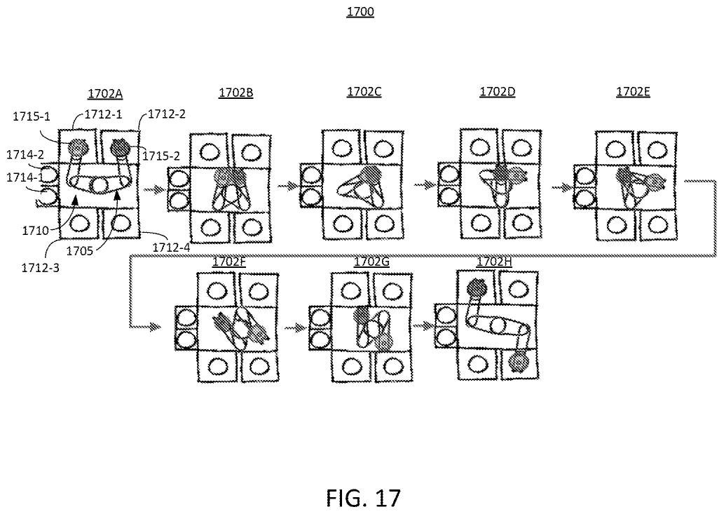

FIG. 17 illustrates a diagram 1700 showing top-down view of operations of robot apparatus 1705 housed within rectangular mainframe 1710, according to some embodiments. In some embodiments, robot apparatus 1705 corresponds to robot apparatus 1500A of FIG. 15A or robot apparatus 1500B of FIG. 15B. Rectangular mainframe 1710 can include first processing chamber 1712-1, second processing chamber 1712-2, third processing chamber 1712-3, fourth processing chamber 1712-4, first load lock chamber 1712-1 and second load lock chamber 1712-2. First processing chamber 1712-1 and second processing chamber 1712-2 are separated by a first pitch and third processing chamber. As further shown, substrate 1715-1 is located within first processing chamber 1712-1 and substrate 1715-2 is located within second processing chamber 1712-2.

During operation 1702A, robot apparatus 1705 extends each end effector of a pair of end effectors into a respective one of first processing chamber 1712-1 and second processing chamber 1712-2. During operation 1702B, robot apparatus 1705 retracts the end effectors into rectangular mainframe 1710 to remove substrate 1715-1 from first processing chamber 1715-1 and substrate 1715-2 from second processing chamber 1712-2. As further shown during operation 1702B, robot apparatus 1705 folds each end effector inward within a sweep diameter defined by a width of rectangular mainframe 1710. During operations 1702C-1702G, robot apparatus 1705 incrementally rotates and maneuvers the pair of end effectors, such that the end effector carrying substrate 1715-1 is directed to first processing chamber 1712-1, and the end effector carrying substrate 1715-2 is directed to fourth processing chamber 175-4 (e.g., approximately perpendicular with respect to the length of rectangular mainframe 1710). During operation 1702H, robot apparatus 1705 can extend the end effector carrying substrate 1715-2 into first processing chamber 1712-1 and the end effector carrying substrate 1715-1 into fourth processing chamber 1714-2 (e.g., simultaneously or consecutively). This can enable robot apparatus 1705 to retract the end effectors after completing the transfer of substrate 1715-2 from second processing chamber 1412-2 to first processing chamber 1412-1, and the transfer of substrate 1715-1 from first processing chamber 1412-1 to fourth processing chamber 1412-4.

The illustrative embodiment of FIG. 17 shows an example of dual substrate transfer of substrates 1715-1 and 1715-2. More specifically, one end effector of robot apparatus 1705 can be passed over the top of the other end effector of robot apparatus 1705 to allow robot apparatus 1705 to have a dual opposite SCARA robot arm configuration. Accordingly, robot apparatus 1705 can simultaneously access processing chambers on opposite sides of rectangular mainframe 1710 when needed for dual substrate handling.

FIGS. 18A-18B illustrate example side views 1800A and 1800B of a robot blade 1860 with a pair of vertically offset end effectors 1862, 1864 and a process chamber 1855, according to some embodiments. Robot blade 1860 can replace end effectors of the robot apparatuses described above (e.g., end effectors 810A and 810B).

The process chamber 1855 includes a substrate receiving area 1865 that includes a set of lift pins 1866. The lift pins 1866 may raise and lower to two different substrate transfer heights (also referred to as pitches) 1852, 1853. A first substrate transfer height 1853 may be used for placing substrates on a lower end effector 1864 and removing substrates from the lower end effector 1864, and a second substrate transfer height may be used for placing substrates on an upper end effector 1862 and for removing substrates from the upper end effector 1862.

FIG. 18A shows removal of a processed wafer 1855 from the process chamber 1855 by blade 1860. In one embodiment, if both end effectors 1862, 1864 are empty, then a processed wafer 1855 is first placed on the upper end effector 1862 at the upper substrate transfer height 1852. A next processed wafer (not shown) is then placed on the lower end effector 1864 at the lower substrate transfer height 1853. This may minimize particles from one substrate falling on another substrate. In embodiments, process chamber 1855 includes a carousel and multiple substrate pockets. Once substrate 1855 is removed from process chamber 1855, the carousel may rotate and an additional processed wafer may be positioned near a chamber port that is accessible by the blade 1860, and the additional processed wafer may be placed on the lower end effector 1864.

FIG. 18B shows placement of a substrate 1874 that has not yet been processed by process chamber 1855 (referred to as an unprocessed substrate) from lower end effector 1864 onto the lift pins 1866 at lower substrate transfer height 1853. In some embodiments, and as shown, upper end effector 1862 can contain another unprocessed substrate 1872. In some embodiments, if the blade 1860 contains two unprocessed substrates 1872, 1874, then the unprocessed substrate 1874 on the lower end effector 1864 is first placed into process chamber 1855, followed by placement of the unprocessed substrate 1872 on the upper end effector 1862. This sequence can further mitigate particle contamination onto substrate 1874.

Furthermore, in instances in which unprocessed substrates are placed into the process chamber 1855 and processed substrates are removed from the process chamber 1855, by first placing from the lower end effector 1864, and then retrieving a processed substrate from the lower end effector 1864 while the upper end effector 1862 still holds an unprocessed substrate further reduces particle contamination on the substrates held on the lower end effector 1864.

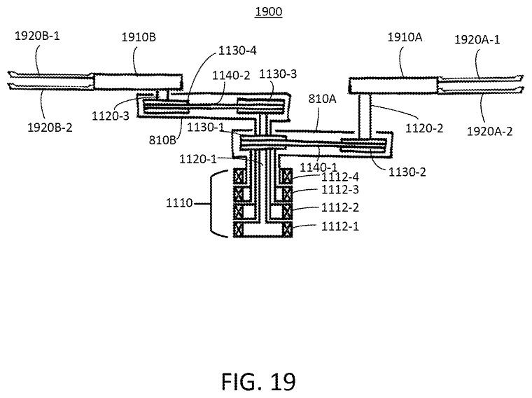

FIG. 19 illustrates an example robot apparatus 1900 having a motion driving assembly according to some embodiments. Robot apparatus 1900 is similar to the robot apparatus 1100B of FIG. 11B, except that, instead of a single end effector, it has blades 1910A and 1910B (e.g., similar to blade 1860 of FIGS. 18A-18B) that include a pair of end effectors 1920A-1 and 1920A-2 and a pair of end effectors 1920B-1 and 1920B-2, respectively (e.g., similar to end effectors 1862 and 1864 of FIGS. 18A-18B). More specifically, end effectors 1920A-1 and 1920B-1 are upper end effectors of their respective pairs and end effectors 1920B-1 and 1920B-2 are lower end effectors of their respective pairs.

In some embodiments, robot apparatus 1900 is similar to the robot apparatus 1100A of FIG. 11A, robot apparatus 1200 of FIG. 12, robot apparatus 1300 of FIG. 13, robot apparatus 1500A of FIG. 15A, or robot apparatus 1500B of FIG. 15B, except that, instead of a single end effector, it has blades 1910A and 1910B (e.g., similar to blade 1860 of FIGS. 18A-18B) that include a pair of end effectors 1920A-1 and 1920A-2 and a pair of end effectors 1920B-1 and 1920B-2, respectively (e.g., similar to end effectors 1862 and 1864 of FIGS. 18A-18B).

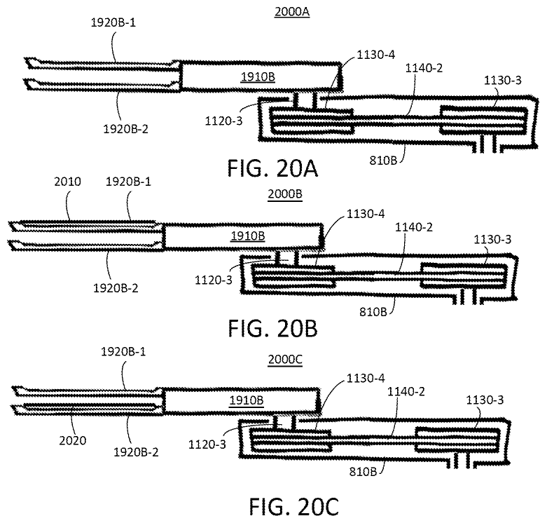

FIG. 20A illustrates a side view 2000A of robot apparatus 1900 including blade 1910B with a pair of end effectors 1920B-1 and 1920B-2, according to some embodiments. In this example, neither end effector of the pair is holding a substrate.

FIG. 20B illustrates side view 2000B of robot apparatus 1900 including blade 1910B with a pair of end effectors 1920B-1 and 1920B-2. More specifically, end effector 1920B-1 (e.g., the upper end effector of the pair) is holding substrate 2010. In some embodiments, substrate 2010 is an unprocessed substrate.

FIG. 20C illustrates side view 2000C of robot apparatus 1900 including blade 1910B with a pair of end effectors 1920B-1 and 1920B-2. The pair of end effectors includes an upper end effector and a lower end effector. More specifically, end effector 1920B-2 (e.g., the lower end effector of the pair) is holding substrate 2020. In some embodiments, substrate 2020 is a processed substrate.

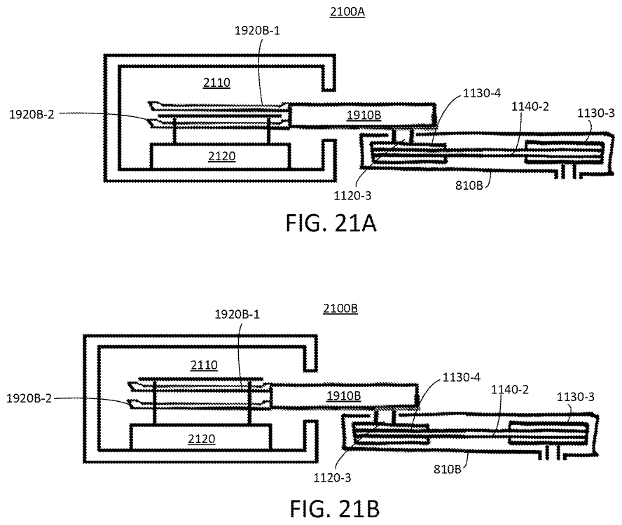

FIG. 21A illustrates a side view 2100A of robot apparatus 1900 including blade 1910B with a pair of end effectors 1920B-1 and 1920B-2, according to some embodiments. More specifically, process chamber 2110 includes lift 2120, and lift 2120 with process chamber 2110 is being used to exchange a substrate on end effector 1920B-2 (e.g., the lower end effector of the pair). In some embodiments, lift 2120 is being used to exchange a processed substrate on end effector 1920B-2.

FIG. 21B illustrates a side view 2100B of robot apparatus 1900 including blade 1910B with a pair of end effectors 1920B-1 and 1920B-2. More specifically, lift 2120 within process chamber 2110 is being used to exchange a substrate on end effector 1920B-1 (e.g., an upper end effector of the pair). In some embodiments, lift 2120 within process chamber 2110 is being used to exchange an unprocessed substrate on end effector 1920B-1.

The foregoing description discloses example embodiments of the disclosure. Modifications of the above-disclosed apparatus, systems, and methods which fall within the scope of the disclosure will be readily apparent to those of ordinary skill in the art. Accordingly, while the present disclosure has been disclosed in connection with example embodiments, it should be understood that other embodiments may fall within the scope of the disclosure, as defined by the claims.

What is claimed is:

1. A robot apparatus, comprising:
a lower arm configured to rotate about a first rotational axis;
an upper arm rotatably coupled to the lower arm at, and configured to rotate about, the first rotational axis;
a first blade comprising at least a first end effector rotatably coupled to the lower arm at, and configured to rotate about, a second rotational axis that is spaced away from the first rotational axis; and
a second blade comprising at least a second end effector rotatably coupled to the upper arm at, and configured to rotate about, a third rotational axis that is spaced away from the first rotational axis;
wherein the robot apparatus is configured to:
extend the first end effector into a first processing chamber and extend the second end effector into a second processing chamber, wherein the first processing chamber and the second processing chamber are separated by a first pitch;
retract the first end effector and the second end effector into a rectangular mainframe while maintaining a distance between the first end effector and the second end effector bounded by the first pitch throughout a retraction process; and
fold the first end effector and the second end effector inward within a sweep diameter defined by a width of the rectangular mainframe.

2. The robot apparatus of claim 1, wherein the first blade and the second blade are each positioned with respect to a common substrate transfer plane.

3. The robot apparatus of claim 1, wherein the first blade is positioned with respect to a first substrate transfer plane, and wherein the second blade is positioned with respect to a second substrate transfer plane vertically offset from the first substrate transfer plane.

4. The robot apparatus of claim 1, wherein the robot apparatus is further configured to:
extend the first end effector into a first load lock chamber and extend the second end effector into a second load lock chamber, the first load lock chamber and the second load lock chamber being separated by a second pitch less than the first pitch; and
retract the first end effector and the second end effector from the first and second load lock chambers and into the rectangular mainframe.

5. The robot apparatus of claim 4, wherein the first end effector and the second end effector are independently extended into, and independently retracted from, the first load lock chamber and the second load lock chamber, respectively.

6. The robot apparatus of claim 4, wherein the first end effector is extended into the first load lock chamber at a first time and the second end effector is extended into the second load lock chamber at a second time after the first time to perform coordination extension and retraction.

7. The robot apparatus of claim 4, wherein the first end effector and the second end effector are simultaneously extended into, and simultaneously retracted from, the first load lock chamber and the second load lock chamber, respectively.

8. The robot apparatus of claim 1, further comprising a motion driving assembly, wherein the motion driving assembly comprises at least one of a 4-theta motor driving assembly, a 3-theta motor driving assembly, or a distributed motor driving assembly.

9. An electronic device processing system, comprising:
a rectangular mainframe;
a first load lock chamber and a second load lock chamber attached to a first side of the rectangular mainframe, wherein a first port of the first load lock chamber and a second port of the second load lock chamber are spaced apart horizontally by a first pitch;
a first processing chamber and a second processing chamber attached to a second side of the rectangular mainframe, wherein a third port of the first processing chamber and a fourth port of the second processing chamber are spaced apart horizontally by a second pitch that is greater than the first pitch; and
a robot apparatus housed within the rectangular mainframe, the robot apparatus comprising:
a lower arm configured to rotate about a first rotational axis;
an upper arm rotatably coupled to the lower arm at, and configured to rotate about, the first rotational axis;
a first blade comprising at least a first end effector rotatably coupled to the lower arm at, and configured to rotate about, a second rotational axis that is spaced away from the first rotational axis; and
a second blade comprising at least a second end effector rotatably coupled to the upper arm at, and configured to rotate about, a third rotational axis that is spaced away from the first rotational axis;
wherein the robot apparatus is configured to:
extend the first end effector into the first processing chamber and extend the second end effector into the second processing chamber;
retract the first end effector and the second end effector into the rectangular mainframe while maintaining a distance between the first end effector and the second end effector bounded by the second pitch throughout retraction; and
fold the first end effector and the second end effector inward within a sweep diameter defined by a width of the rectangular mainframe.

10. The electronic device processing system of claim 9, wherein the first blade and the second blade are each positioned with respect to a common substrate transfer plane.

11. The electronic device processing system of claim 9, wherein the first blade is positioned with respect to a first substrate transfer plane, and wherein the second blade is positioned with respect to a second substrate transfer plane vertically offset from the first substrate transfer plane.

12. The electronic device processing system of claim 9, wherein the robot apparatus is further configured to:
extend the first end effector into a first load lock chamber and extend the second end effector into a second load lock chamber; and
retract the first end effector and the second end effector from the first and second load lock chambers and into the rectangular mainframe.

13. The electronic device processing system of claim 12, wherein the first end effector and the second end effector are independently extended into, and independently retracted from, the first load lock chamber and second load lock chamber, respectively.

14. The electronic device processing system of claim 12, wherein the first end effector is extended into the first load lock chamber at a first time and the second end effector is extended into the second load lock chamber at a second time after the first time to perform coordination extension and retraction.

15. The electronic device processing system of claim 12, wherein the first and second end effectors are simultaneously extended into, and simultaneously retracted from, the first and second load lock chambers, respectively.

16. A method comprising:
for a robot apparatus comprising:
a lower arm configured to rotate about a first rotational axis;
an upper arm rotatably coupled to the lower arm at, and configured to rotate about, the first rotational axis;
a first blade comprising at least a first end effector rotatably coupled to the lower arm at, and configured to rotate about, a second rotational axis that is spaced away from the first rotational axis; and
a second blade comprising at least a second end effector rotatably coupled to the upper arm at, and configured to rotate about, a third rotational axis that is spaced away from the first rotational axis:
extending, by the robot apparatus, the first end effector into a first processing chamber to retrieve a first substrate;
extending, by the robot apparatus, the second end effector into a second processing chamber to retrieve a second substrate, wherein the first processing chamber and the second processing chamber are separated by a first pitch;
retracting, by the robot apparatus, the first end effector and the second end effector into a rectangular mainframe while maintaining a distance between the first end effector and the second end effector bounded by the first pitch throughout retraction; and
folding, by the robot apparatus, the first end effector and the second end effector inward within a sweep diameter defined by a width of the rectangular mainframe.

17. The method of claim 16, further comprising:
extending, by the robot apparatus, the first end effector into a first load lock chamber to retrieve a first substrate and extend the second end effector into a second load lock chamber to retrieve a second substrate, wherein the first load lock chamber and the second load lock chamber are separated by a second pitch that is less than the first pitch; and
after retrieving the first and second substrates from the first and second load lock chamber and the second load lock chamber, retracting the first end effector and the second end effector from the first load lock chamber and the second load lock chamber and into the rectangular mainframe.

18. The method of claim 17, wherein the first end effector and the second end effector are independently extended into, and independently retracted from, the first load lock chamber and the second load lock chamber, respectively.

19. The method of claim 17, wherein the first end effector is extended into the first load lock chamber at a first time and the second end effector is extended into the second load lock chamber at a second time after the first time to perform coordination extension and retraction.

20. The method of claim 17, wherein the first end effectors and the second end effector are simultaneously extended into, and simultaneously retracted from, the first load lock chamber and the second load lock chamber, respectively.
